(19) United States
(12) Patent Application Publication
(10) Pub. No.: US 2026/0033403 A1
(43) Pub. Date: Jan. 29, 2026

(54) MULTI-LEVEL 3D STACKED PACKAGE AND METHODS OF FORMING THE SAME

(71) Applicant: Qorvo US, Inc., Greensboro, NC (US)

(72) Inventors: Julio C. Costa, Oak Ridge, NC (US); George Maxim, Saratoga, CA (US); Baker Scott, San Jose, CA (US)

(21) Appl. No.: 19/348,412

(22) Filed: Oct. 2, 2025

Related U.S. Application Data
(63) Continuation of application No. 18/254,162, now Pat. No. 12,482,731.
(60) Provisional application No. 63/124,456, filed on Dec. 11, 2020.

(51) Int. Cl. H01L 23/498; H01L 23/00; H01L 25/065

(52) U.S. Cl. CPC H01L 23/49816; H01L 23/49822; H01L 24/16; H01L 24/32; H01L 24/73; H01L 25/0657; H01L 2224/16146; H01L 2224/16235; H01L 2224/32146; H01L 2224/32235; H01L 2224/73253; H01L 2225/06517; H01L 2225/06586; H01L 2924/15321; H01L 2924/182

(57) ABSTRACT

The present disclosure relates to a multi-level three-dimensional (3D) package with multiple package levels vertically stacked. Each package level includes a redistribution structure and a die section over the redistribution structure. Each die section includes a thinned die that includes substantially no silicon substrate and has a thickness between several micrometers and several tens of micrometers, a mold compound, and an intermediary mold compound. Herein, the thinned die and the mold compound are deposed over the redistribution structure, the mold compound surrounds the thinned die and extends vertically beyond a top surface of the thinned die to define an opening over the thinned die and within the mold compound, the intermediary mold compound resides over the thinned die and fills the opening within the inner mold compound, such that a top surface of the intermediary mold compound and a top surface of the mold compound are coplanar.

### RELATED APPLICATIONS

This application is a continuation of U.S. patent application Ser. No. 18/254,162, filed May 23, 2023, which is a national phase filing of PCT/US2021/063094, filed Dec. 13, 2021, which claims the benefit of provisional patent application Ser. No. 63/124,456, filed Dec. 11, 2020, the disclosures of which are hereby incorporated herein by reference in their entireties.

### FIELD OF THE DISCLOSURE

The present disclosure relates to a multi-level three-dimensional (3D) package and a process for making the same, and more particular to a multi-level 3D package with stacked thinned dies on wafer-level-fan-out (WLFO) assemblies, and a wafer-level packaging process to provide the multi-level 3D package with multiple thinned dies that are vertically stacked.

### BACKGROUND

With the popularity of portable consumer electronic products, such as smart phones, tablet computers, and so forth, stacked-die assemblies are becoming more and more attractive in microelectronics packages to achieve electronics densification in a small footprint. However, the thickness of each stacked semiconductor die may result in a large thickness of the microelectronics package, which may not meet low-profile requirements for modern portable products. Such low-profile requirements significantly limit the number of semiconductor dies that can be stacked.

In most semiconductor dies, all signal processing is performed in a very thin portion of the die. The rest of the majority of the semiconductor die (height up to 150 μm or more) is the semiconductor substrate, which is useless for the signal processing. The thick semiconductor substrate is useful only during the die handling and assembly to provide mechanical stability.

On the other hand, for the portable radio frequency (RF) applications, wafer-level fan-out (WLFO) packaging technology is widely applied to provide high density input/output ports (I/O) without increasing the size of a package. This capability of the WLFO packaging technology allows for densely packaging the semiconductor dies within a single wafer.

Accordingly, to accommodate the low-profile requirements for portable products, and to utilize advantages of WLFO packaging technology, it is therefore an object of the present disclosure to provide an improved package design with a reduced package size without sacrificing signal processing performance.

### SUMMARY

The present disclosure relates to a multi-level three-dimensional (3D) package with stacked thinned dies on wafer-fan-out (WFO) assemblies and a process for making the same. The disclosed multi-level 3D package includes a lower package level and an upper package level over the lower package level. The lower package level includes a lower redistribution structure and a lower die section over the lower redistribution structure. Herein, the lower die section includes a lower thinned die, a lower mold compound, a lower intermediary mold compound, and lower vertical via structures. The lower thinned die and the lower mold compound are deposed over the lower redistribution structure, the lower mold compound surrounds the lower thinned die and extends vertically beyond a top surface of the lower thinned die to define a lower opening over the lower thinned die and within the lower mold compound, the lower intermediary mold compound resides over the lower thinned die and fills the lower opening within the lower mold compound, and each lower vertical via structure extends through the lower mold compound. The lower thinned die includes substantially no silicon substrate and has a thickness between several micrometers and several tens of micrometers. A top surface of the lower intermediary mold compound and a top surface of the lower mold compound are coplanar. In addition, the upper package level includes an upper redistribution structure over the lower package level and an upper die section over the upper redistribution structure. Herein, the upper die section includes an upper thinned die, an upper mold compound, and an upper intermediary mold compound. The upper thinned die and the upper mold compound are deposed over the upper redistribution structure, the upper mold compound surrounds the upper thinned die and extends vertically beyond a top surface of the upper thinned die to define an upper opening over the upper thinned die and within the upper mold compound, and the upper intermediary mold compound resides over the upper thinned die and fills the upper opening within the upper mold compound. The upper thinned die includes substantially no silicon substrate and has a thickness between several micrometers and several tens of micrometers. A top surface of the upper intermediary mold compound and a top surface of the upper mold compound are coplanar.

In one embodiment of the multi-level 3D package, the lower redistribution structure includes a lower dielectric pattern and lower redistribution interconnections within the lower dielectric pattern, and the upper redistribution structure includes an upper dielectric pattern and upper redistribution interconnections within the upper dielectric pattern. Herein, the lower thinned die is connected to the upper thinned die through the lower redistribution interconnections in the lower redistribution structure, the lower vertical via structures in the lower die section, and the upper redistribution interconnections in the upper redistribution structure.

According to one embodiment, the multi-level 3D package further includes a number of bump structures formed underneath the lower redistribution structure. Herein, each bump structure is connected to the lower redistribution interconnections through the lower dielectric pattern. The bump structures are separate from each other and protrude from the lower dielectric pattern. The bump structures are copper pillars or solder balls.

According to one embodiment, the multi-level 3D package further includes one or more un-thinned components residing underneath the lower redistribution structure of the lower die section. Herein, each un-thinned component has a thickness between 100 micrometers and several hundreds of micrometers. The one or more un-thinned components are configured to be connected to the lower thinned die through the lower redistribution interconnections. Each bump structure has a same height and is taller than one or more un-thinned components.

According to one embodiment, the multi-level 3D package further includes one or more inner package levels vertically stacked between the lower package level and the upper package level. Herein, each inner package levels includes an inner redistribution structure and an inner die section over the inner redistribution structure. Each inner die section includes an inner thinned die, an inner mold compound, an inner intermediary mold compound, and inner vertical via structures. Herein, the inner thinned die and the inner mold compound are deposed over the inner redistribution structure, the inner mold compound surrounds the inner thinned die and extends vertically beyond a top surface of the inner thinned die to define an inner opening over the inner thinned die and within the inner mold compound, the inner intermediary mold compound resides over the inner thinned die and fills the inner opening within the inner mold compound, and each inner vertical via structure extends through the inner mold compound. The inner thinned die includes substantially no silicon substrate and has a thickness between several micrometers and several tens of micrometers. A top surface of the inner intermediary mold compound and a top surface of the inner mold compound are coplanar.

In one embodiment of the multi-level 3D package, each inner redistribution structure includes an inner dielectric pattern and inner redistribution interconnections within the inner dielectric pattern. The lower thinned die, the inner thinned die in each of the one or more package levels, and the upper thinned die are connected through the lower redistribution interconnections in the lower redistribution structure, the lower vertical via structures in the lower die section, the inner redistribution interconnections in each inner redistribution structure, the inner vertical via structures in each inner die section, and the upper redistribution interconnections in the upper redistribution structure.

In one embodiment of the multi-level 3D package, at least one inner die section includes a number of thinned dies including the inner thinned die. The at least one inner die section includes a number of intermediary mold compounds including the inner intermediary mold compound. Each thinned die is deposed over the inner redistribution structure and surrounded by the inner mold compound, where the inner mold compound extends vertically beyond a top surface of each thinned die to define an opening over each thinned die and within the inner mold compound. Each intermediary mold compound resides over a corresponding thinned die and fills a corresponding opening within the inner mold compound. Each thinned die includes substantially no silicon substrate and has a thickness between several micrometers and several tens of micrometers. A top surface of each intermediary mold compound and a top surface of the inner mold compound are coplanar.

According to one embodiment, the multi-level 3D package further includes a top protection structure over the upper die section of the upper package level. Herein, the top protection structure is in contact with the upper mold compound and the upper intermediary mold compound in the upper die section. The top protection structure is configured to provide chemical and gas/air contamination protection.

According to one embodiment, the multi-level 3D package further includes a metal shield over the top protection structure. The metal shield is configured to provide electromagnetic shielding of the multi-level 3D package.

In one embodiment of the multi-level 3D package, the upper intermediary mold compound is formed of one of organic epoxy resin system, a molding material with a thermal conductivity higher than 50 W/mK, a molding material with a magnetic permeability higher than 50, and a molding material with an electric permittivity higher than 10. The lower intermediary mold compound is formed of one of organic epoxy resin system, a molding material with a thermal conductivity higher than 50 W/mK, a molding material with a magnetic permeability higher than 50, and a molding material with an electric permittivity higher than 10.

In one embodiment of the multi-level 3D package, the upper thinned die and the lower thinned die are different types of dies.

In one embodiment of the multi-level 3D package, the upper intermediary mold compound and the lower intermediary mold compound are formed of different materials.

In one embodiment of the multi-level 3D package, at least one of the upper thinned die and the lower thinned die is an active die, which includes an insulating layer, an active layer underneath the insulating layer, and a back-end-of-line (BEOL) portion underneath the active layer. The active layer is configured to provide one or more active devices. The BEOL portion includes dielectric layers and metal structures within the dielectric layers, where the metal structures are configured to connect the active devices in the active layer to each other and/or configured to connect the active devices in the active layer to external components.

In one embodiment of the multi-level 3D package, the active die is formed from a silicon-on-insulator (SOI) structure. The active layer of the active die is formed by integrating the one or more active devices in or on a silicon epitaxy layer of the SOI structure, and the insulating layer of the active die is a buried oxide layer of the SOI structure.

In one embodiment of the multi-level 3D package, at least one of the upper thinned die and the lower thinned die is a passive die, which includes an insulating layer and a BEOL portion underneath the insulating layer. The BEOL portion includes dielectric layers and metal structures within the dielectric layers, where the metal structures are configured to provide one or more passive devices and configured to connect the passive devices to external components.

According to one embodiment, the multi-level 3D package further includes a top redistribution structure over the upper die section of the upper package level. Herein, the upper die section further includes upper vertical via structures, each of which extends through the upper mold compound. The top redistribution structure includes a top dielectric pattern and top redistribution interconnections within the top dielectric pattern. The top redistribution interconnections are configured to be connected to the upper vertical via structures.

According to one embodiment, the multi-level 3D package further includes one or more un-thinned components residing over the top redistribution structure. Herein, each un-thinned component has a thickness between 100 micrometers and several hundreds of micrometers. The upper redistribution structure includes an upper dielectric pattern and upper redistribution interconnections within the upper dielectric pattern. The one or more un-thinned components are configured to be connected to the upper thinned die through the top redistribution interconnections, the upper vertical via structures, and the upper redistribution interconnections.

In one embodiment of the multi-level 3D package, each un-thinned component is one of a gallium arsenide (GaAs) die, a complementary metal-oxide-semiconductor (CMOS) die, and a surface mounted device (SMD).

In one embodiment of the multi-level 3D package, the lower die section includes a number of thinned dies including the lower thinned die. The lower die section includes a number of intermediary mold compounds including the lower intermediary mold compound. Each thinned die is deposed over the lower redistribution structure and surrounded by the lower mold compound, where the lower mold compound extends vertically beyond a top surface of each thinned die to define an opening over each thinned die and within the lower mold compound. Each intermediary mold compound resides over a corresponding thinned die and fills a corresponding opening within the lower mold compound. Each thinned die includes substantially no silicon substrate and has a thickness between several micrometers and several tens of micrometers. A top surface of each intermediary mold compound and a top surface of the lower mold compound are coplanar.

In one embodiment of the multi-level 3D package, the upper die section includes a number of thinned dies including the upper thinned die. The upper die section includes a number of intermediary mold compounds including the upper intermediary mold compound. Each thinned die is deposed over the upper redistribution structure and surrounded by the upper mold compound, where the upper mold compound extends vertically beyond a top surface of each thinned die to define an opening over each thinned die and within the upper mold compound. Each intermediary mold compound resides over a corresponding thinned die and fills a corresponding opening within the upper mold compound. Each thinned die includes substantially no silicon substrate and has a thickness between several micrometers and several tens of micrometers. A top surface of each intermediary mold compound and a top surface of the upper mold compound are coplanar.

In one embodiment of the multi-level 3D package, the thinned dies in the lower die section and the thinned dies in the upper die section have different numbers of dies.

In one embodiment of the multi-level 3D package, the thinned dies in the lower die section and the thinned dies in the upper die section have different layouts.

In one embodiment of the multi-level 3D package, the thinned dies in the lower die section and the thinned dies in the upper die section provide different functionalities.

In one embodiment of the multi-level 3D package, the thinned dies in the lower die section achieves a receiver functionality, while the thinned dies in the upper die section achieves a transmitter functionality. The upper redistribution structure between the lower die section and the upper die section includes an isolation metal shield to isolate signals in the lower die section and the upper die section.

According to an exemplary process, a lower die section is firstly provided over a module carrier. The lower die section includes a lower thinned die, a lower mold compound, a lower intermediary mold compound, and lower vertical via structures. Herein, the lower thinned die and the lower mold compound are deposed over the module carrier, the lower mold compound surrounds the lower thinned die and extends vertically beyond a top surface of the lower thinned die to define a lower opening over the lower thinned die and within the lower mold compound, the lower intermediary mold compound resides over the lower thinned die and fills the lower opening within the lower mold compound, and each lower vertical via structure extends through the lower mold compound. The lower thinned die includes substantially no silicon substrate and has a thickness between several micrometers and several tens of micrometers. A top surface of the lower intermediary mold compound and a top surface of the lower mold compound are coplanar. Next, an upper redistribution structure is formed over the lower die section. An upper die section is then provided over the upper redistribution structure. The upper die section includes an upper thinned die, an upper mold compound, and an upper intermediary mold compound. Herein, the upper thinned die and the upper mold compound are deposed over the upper redistribution structure, the upper mold compound surrounds the upper thinned die and extends vertically beyond a top surface of the upper thinned die to define an upper opening over the upper thinned die and within the upper mold compound, and the upper intermediary mold compound resides over the upper thinned die and fills the upper opening within the upper mold compound. The upper thinned die includes substantially no silicon substrate and has a thickness between several micrometers and several tens of micrometers. A top surface of the upper intermediary mold compound and a top surface of the upper mold compound are coplanar.

In one embodiment of the exemplary process, providing the lower die section starts with providing a lower precursor module, which includes the module carrier, a lower intact die deposed over the module carrier, and the lower mold compound that resides over the module carrier and fully encapsulates the lower intact die. Herein, the lower intact die includes a lower device region over the module carrier and a lower die substrate over the lower device region, such that a backside of the lower die substrate is a top surface of the lower intact die. Next, the lower mold compound is thinned down to expose the backside of the lower die substrate. The lower die substrate is then substantially removed to provide the lower thinned die and define the lower opening over the lower thinned die and within the lower mold compound. The lower intermediary mold compound is applied over the lower thinned die to provide a lower molding precursor. A polishing process is followed to polish the lower mold precursor, such that the top surface of the lower intermediary mold compound and the top surface of the lower mold compound are coplanar. A number of lower vertical via holes are formed through the lower mold compound, and the lower vertical via structures are formed in the lower vertical via holes to complete the lower die section.

In one embodiment of the exemplary process, providing the lower die section starts with attaching an upper intact die to the upper redistribution structure, where the upper intact die includes an upper device region over the upper redistribution structure and an upper die substrate over the upper device region, such that a backside of the upper die substrate is a top surface of the upper intact die. Next, the upper mold compound is applied over the upper redistribution structure to fully encapsulate the upper intact die. The upper mold compound is then thinned down to expose the backside of the upper die substrate. The upper die substrate is removed substantially to provide the upper thinned die and define the upper opening over the upper thinned die and within the upper mold compound. The upper intermediary mold compound is applied over the upper thinned die to provide an upper molding precursor. A polishing process is followed to polish the upper molding precursor, such that the top surface of the upper intermediary mold compound and the top surface of the upper mold compound are coplanar.

In one embodiment of the exemplary process, providing the lower die section starts with providing a lower precursor module, which includes the module carrier, a lower intact die deposed over the module carrier, lower vertical via structures deposed over the module carrier, and the lower mold compound that resides over the module carrier, fully encapsulates the lower intact die, and fully encapsulates each lower vertical via structure. Herein, the lower intact die includes a lower device region over the module carrier and a lower die substrate over the lower device region, such that a backside of the lower die substrate is a top surface of the lower intact die. Each lower vertical via structure has a same height, is shorter than the lower intact die, and is taller than the lower device region. Next, the lower mold compound is thinned down to expose the backside of the lower die substrate. The lower die substrate is removed substantially to provide the lower thinned die and define the lower opening over the lower thinned die and within the lower mold compound. The lower intermediary mold compound is applied over the lower thinned die to provide a lower molding precursor. A polishing process is followed to polish the lower mold precursor to provide the lower die section. Herein, the lower intermediary mold compound and the lower mold compound are thinned down by polishing until a top surface of each lower vertical via structure is exposed through the lower mold compound.

In one embodiment of the exemplary process, providing the lower precursor module starts with attaching the lower intact die to the module carrier. Next, seed layers are deposited over the module carrier and around the lower intact die. One or more metal/alloy materials are applied over each seed layer to form the lower vertical via structures. The lower mold compound is then applied over the module carrier to fully encapsulate the lower intact die and each lower vertical via structure.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates a three-dimensional (3D) package with a stacked-die structure.

FIGS. 2A-2C illustrate an exemplary multi-level 3D package with multiple thinned dies that are vertically stacked according to one embodiment of the present disclosure.

FIGS. 3-5E illustrate an alternative multi-level 3D package according to one embodiment of the present disclosure.

FIGS. 6A-36 provide exemplary steps that illustrate a process to fabricate the exemplary FEM shown in FIG. 2A.

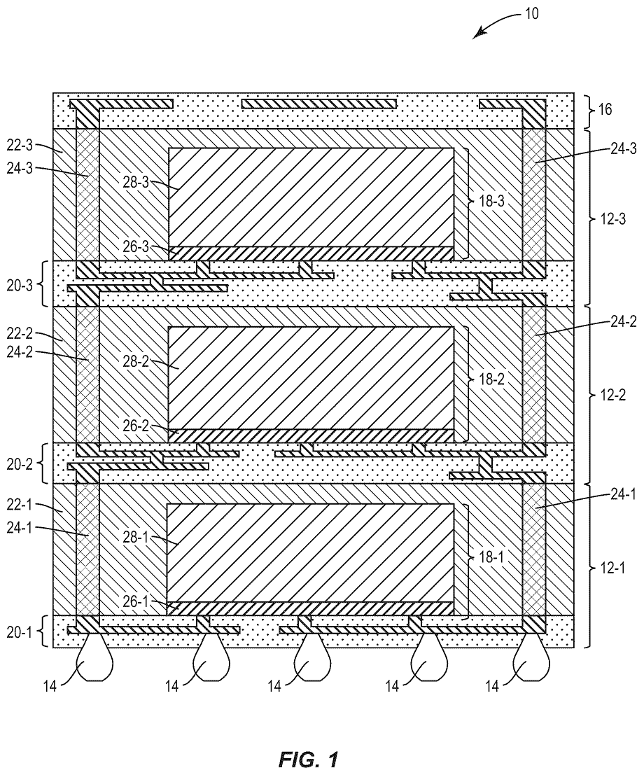

It will be understood that for clear illustrations, FIGS. 1-36 may not be drawn to scale.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

In many radio frequency (RF) products and applications, package modules, like front-end modules, may include multiple semiconductor dies and components, such as one or more power amplifier active dies, one or more low-noise amplifier active dies, one or more switch active dies, and one or more filter structures (LC filter/BAW filter/SAW filter/FBAR filter). In order to save footprint of the package size, a stacked-die structure may be utilized in packaging. FIG. 1 illustrates a three-dimensional (3D) package 10 with a stacked-die structure. The 3D package 10 includes multiple package levels 12 (e.g., a first package level 12-1, a second package level 12-2, and a third package level 12-3), multiple bump structures 14, and a top redistribution structure 16. Herein, the bump structures 14 are formed underneath the first package level 12-1, the second package level 12-2 resides over the first package level 12-1, the third package level 12-3 resides over the second package level 12-2, and the top redistribution structure 16 resides over the third package level 12-3.

For each package level 12, there includes a semiconductor die 18 (e.g., a first semiconductor die 18-1, a second semiconductor die 18-2, and a third semiconductor die 18-3, respectively), a redistribution structure 20 underneath the semiconductor die 18 (e.g., a first redistribution structure 20-1, a second redistribution structure 20-2, and a third redistribution structure 20-3 underneath the first semiconductor die 18-1, the second semiconductor die 18-2, and the third semiconductor die 18-3, respectively), and a mold compound 22 resides over the redistribution 20 to encapsulate the semiconductor die 18 (e.g., a first mold compound 22-1, a second mold compound 22-2, and a third mold compound 22-3, respectively). As such, these semiconductor dies 18 are vertically stacked. In addition, the 3D package 10 may also include multiple through-molding-vias (TMVs) 24 (e.g., first TMVs 24-1, second TMVs 24-2, and third TMVs 24-3, respectively), each of which extends through a corresponding mold compound 22, and is configured to electrically connect the semiconductor dies 18 in different package levels 12 and/or external components outside the three package levels 12.

A main drawback of the 3D package 10 with such stacked-die structure is that the overall height is relatively large, and in most cases is not compatible with low-profile modern mobile assemblies at 0.8 mm, 0.65 mm or 0.5 mm. To meet the low-profile requirements, the 3D package 10 may only include a very limited number of vertically stacked package levels with a standard height in several hundreds of micrometers (e.g., >300 micrometers). The low-profile module with heights below 0.8 mm or 0.65 mm may allow only two semiconductor dies to be stacked. On the other hand, each semiconductor die 18 includes a device region 26 (i.e., a first device region 26-1, a second device region 26-2, and a third device region 26-3, respectively) over the corresponding redistribution structure 20, and a silicon substrate 28 (e.g., a first silicon substrate 28-1, a second silicon substrate 28-2, and a third silicon substrate 28-3, respectively) over a corresponding device region 26. Typically, each device region 26 may have a thickness with a few tens of micrometers or less, while each silicon substrate 28 may have a thickness of a few hundreds of micrometers. These thick silicon substrates 28 take a majority portion of the height of the 3D package 10. However, the thick silicon substrates 28 do not have an active role in signal processing for the semiconductor dies 18, but merely provide mechanical stability when the redistribution structures 20 are formed underneath the corresponding semiconductor dies 18, respectively, and when the mold compounds 22 are applied to encapsulate corresponding semiconductor dies 18, respectively.

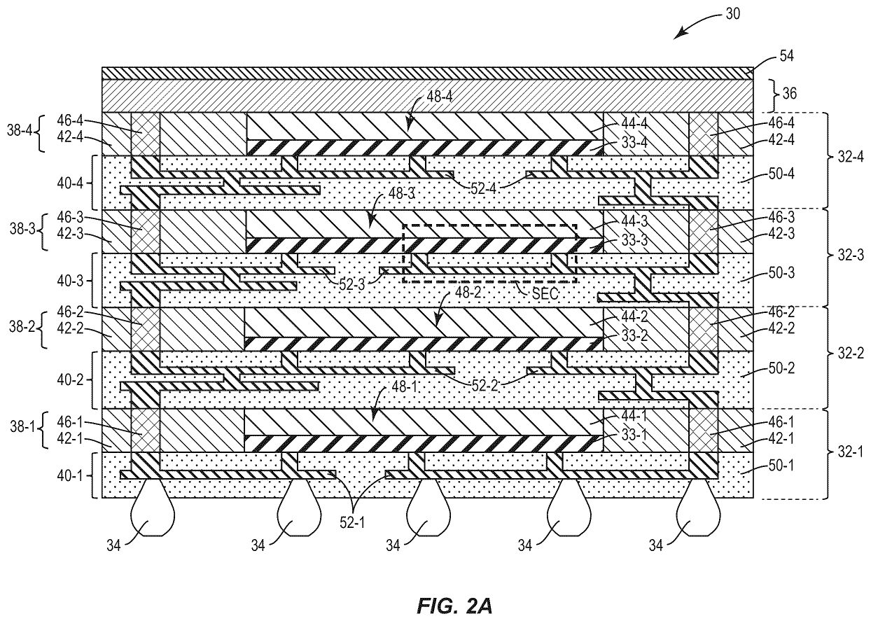

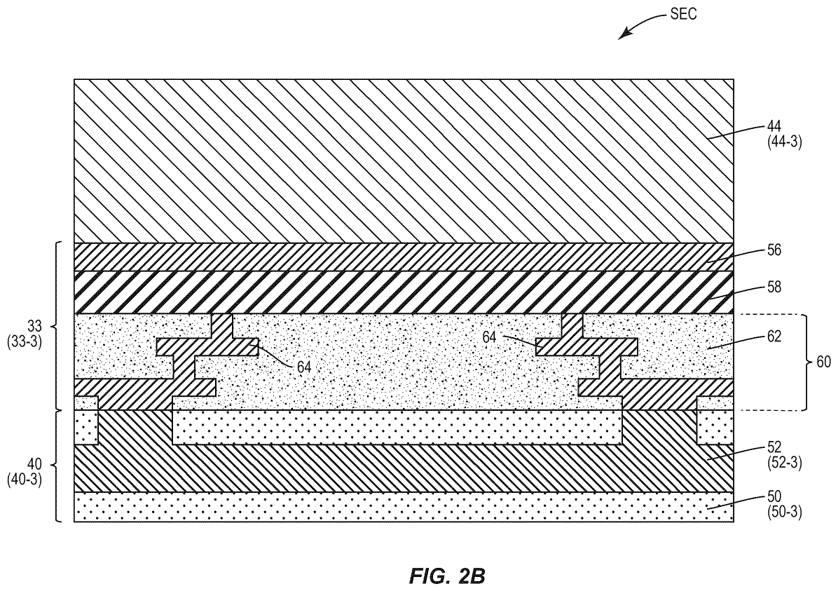

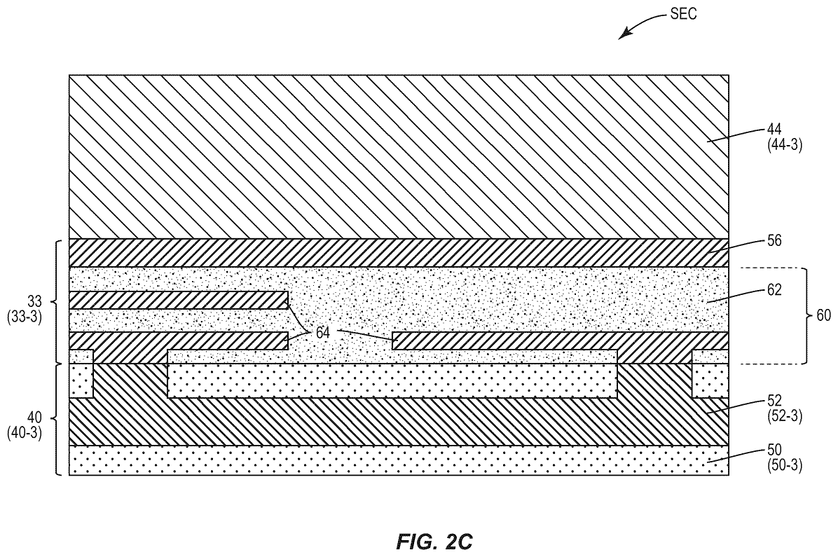

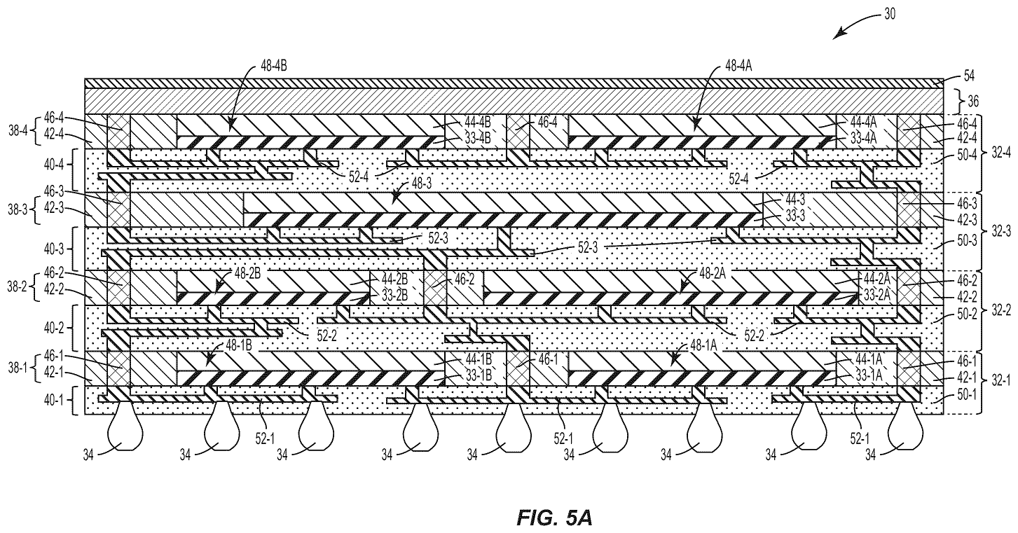

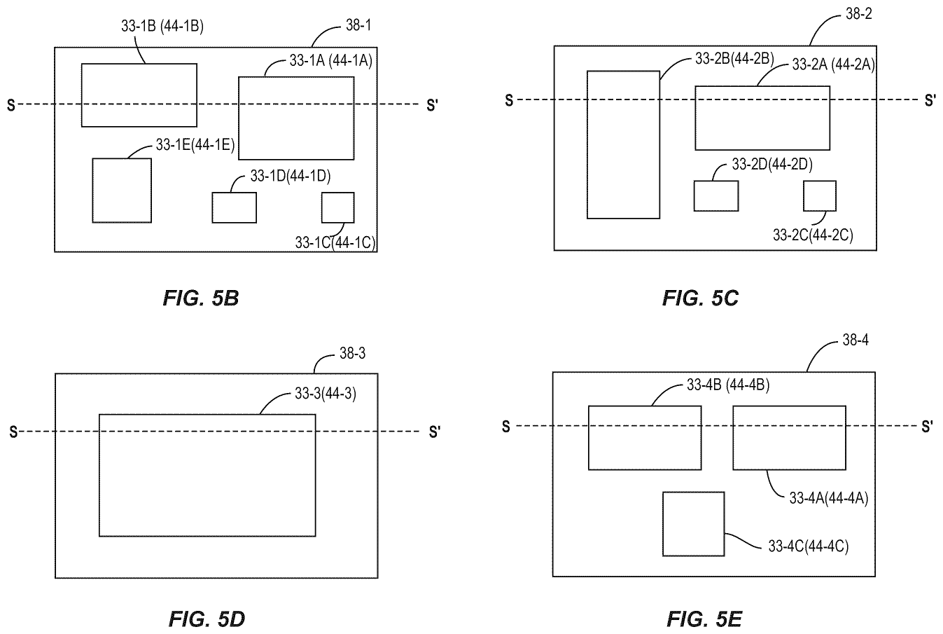

In order to accommodate more semiconductor dies vertically stacked in one 3D package, the height of each package level needs to be reduced. It is also required that the signal processing performance of the semiconductor dies is not sacrificed. FIGS. 2A-2C illustrate an exemplary multi-level 3D package 30 with multiple thinned dies that are vertically stacked according to one embodiment of the present disclosure. For the purpose of this illustration, the exemplary multi-level 3D package 30 includes four package levels 32 (e.g., a first package level 32-1, a second package level 32-2, a third package level 32-3, and a fourth package level 32-4), each of which includes a thinned die 33 (e.g., a first thinned die 33-1, a second thinned die 33-2, a third thinned die 33-3, and a fourth thinned die 33-4, respectively, in the four package levels 32-1˜32-4), multiple bump structures 34, and a top protection structure 36. Herein, the bump structures 34 are formed underneath the first package level 32-1, the second package level 32-2 resides over the first package level 32-1, the third package level 32-3 resides over the second package level 32-2, the fourth package level 32-4 resides over the third package level 32-3, and the top protection structure 36 resides over the fourth package level 32-4. As such, the first, second, third, and fourth thinned dies 33-1˜33-4 are vertically stacked. In different applications, the multi-level 3D package 30 may include fewer or more package levels 32, and each package level 32 may have different numbers of thinned dies 33 (see FIG. 5 below).

In detail, each package level 32 includes a die section 38 (e.g., a first die section 38-1, a second die section 38-2, a third die section 38-3, and a fourth die section 38-4, respectively, in the four package levels 32-1˜32-4), and a redistribution structure 40 underneath the die section 38 (e.g., a first redistribution structure 40-1, a second redistribution structure 40-2, a third redistribution structure 40-3, and a fourth redistribution structure 40-4 underneath the first die section 38-1, the second die section 38-2, the third die section 38-3, and the fourth die section 38-4, respectively). Each die section 38 includes one thinned die 33 (the first thinned die 33-1, the second thinned die 33-2, the third thinned die 33-3, and the fourth thinned die 33-4, respectively, in the four die sections 38-1˜38-4), a mold compound 42 (e.g., a first mold compound 42-1, a second mold compound 42-2, a third mold compound 42-3, and a fourth mold compound 42-4, respectively, in the four die sections 38-1˜38-4), an intermediary mold compound 44 (e.g., a first intermediary mold compound 44-1, a second intermediary mold compound 44-2, a third intermediary mold compound 44-3, and a fourth intermediary mold compound 44-4, respectively, in the four die sections 38-1˜38-4), and multiple vertical via structures 46 (e.g., first vertical via structures 46-1, second vertical via structures 46-2, third vertical via structures 46-3, and fourth vertical via structures 46-4, respectively, in the four die sections 38-1˜38-4). Herein, each thinned die 33 and each mold compound 42 are deposed over a corresponding redistribution structure 40. The mold compound 42 surrounds the thinned die 33 and extends vertically beyond a top surface of the thinned die 33 to define one opening 48 (e.g., a first opening 48-1, a second opening 48-2, a third opening 48-3, and a fourth opening 48-4, respectively, in the four die sections 38-1˜38-4) over the thinned die 33 and within the mold compound 42. Each intermediary mold compound 44 resides over a corresponding thinned die 33 and fills a corresponding opening 48 within the corresponding mold compound 42, where a top surface of one intermediary mold compound 44 and a top surface of a corresponding mold compound 42 are coplanar.

In addition, each redistribution structure 40, which is formed underneath the corresponding die section 38, includes a dielectric pattern 50 (e.g., a first dielectric pattern 50-1, a second dielectric pattern 50-2, a third dielectric pattern 50-3, and a fourth dielectric pattern 50-4, respectively, in the four redistribution structures 40-1˜40-4) and a number of redistribution interconnections 52 (e.g., redistribution interconnections 52-1, second redistribution interconnections 52-2, third redistribution interconnections 52-3, and fourth redistribution interconnections 52-4, respectively, in the four redistribution structures 40-1˜40-4) within the dielectric pattern 50. Herein, the redistribution interconnections 52 are configured to connect the thinned dies 33 on a same package level (see FIG. 5 below) or connect the thinned dies 33 on adjacent package levels. For the first package level 32-1, the first redistribution interconnections 52-1 are further configured to be coupled to the bump structures 34 through the first dielectric pattern 50-1. The bump structures 34, which might be copper pillars or solder balls, are separate from each other and protrude from the first dielectric pattern 50-1.

Furthermore, each vertical via structure 46 extends through the corresponding mold compound 42 and is configured to transmit heat and/or signals among different package levels. For the first, second, and third package levels 32-1˜32-3, the vertical via structures 46-1˜46-3 are configured to electrically and/or thermally connect the thinned dies 33 in different die sections 38 through the redistribution interconnections 52 in different redistribution structures 40. Consequently, the bump structures 34 are electrically/thermally connected to each thinned die 33 through the redistribution interconnections 52 and the vertical via structures 46. For the fourth package level 32-4, the fourth vertical via structures 46-4 are configured to transmit heat and/or signals between the fourth package level 32-4 and external components. In some applications, the fourth vertical via structures 46-4 might be omitted if no electrical components are deposed over the fourth die section 38-1. In this embodiment, the top protection structure 36 is deposed over the fourth package level 32-4 (i.e., over the fourth mold compound 42-4 and the fourth intermediary mold compound 44-4) and coupled to the fourth vertical via structures 46-4, and an additional metal shield 54 is deposed over the top protection structure 36. The top protection structure 36 is configured to provide chemical and gas/air contamination protection, so as to provide isolation of the multi-level 3D package 30. The top protection structure 36 may have a thickness from few tens of micrometers to about 100 micrometers or about 200 micrometers. The metal shield 54 is configured to provide electromagnetic shielding of the multi-level 3D package 30 and may have a thickness from fractions of a micrometer to several micrometers. In some applications, the metal shield 54 may be omitted.

Herein, each mold compound 42 may be formed of multi-particle materials and always has a same thickness as a combination of the corresponding thinned die 33 and the corresponding intermediary mold compound 44. Planarization steps may be used to ensure that each package level 32 is ready for the next step of stacking. Each vertical via structure 46 may be a TMV or a Via-Bar insert. The Via-Bar inserts may be printed circuit board (PCB) based, metal post based or any other metal and insulator pre-fabricated structure. The top protection structure 36 may be formed of molding materials and optionally one or more glass-type materials sealing at a top of the top protection structure 36. The metal shield 54 may be formed of copper, aluminum or other metals or alloys.

In different applications, each package level 32 may include single or multiple thinned dies 33. In different package levels, a number of the thinned dies 33 might be different, and/or the thinned dies 33 might be different types of dies. For instance, the first thinned die 33-1 and the second thinned die 33-2 might be active dies, such as a power amplifier active die, a low-noise amplifier active die, or a switch active die, while the third thinned die 33-3 and the fourth thinned die 33-4 might be passive dies, such as a passive filter die (LC filter/BAW filter/SAW filter/FBAR filter), or a transformer die. FIGS. 2B and 2C show structure details of one thinned die 33 in a dashed box SEC in FIG. 2A.

As illustrated in FIG. 2B, the thinned die 33 is an active die, which includes an insulating layer 56, an active layer 58 underneath the insulating layer 56, and a back-end-of-line (BEOL) portion 60 underneath the active layer 58. The active layer 58 is configured to provide one or more active devices (e.g., devices with one or more transistors, such as a power amplifier, a low-noise amplifier, and a switch). The BEOL portion 60 includes dielectric layers 62 and metal structures 64 within the dielectric layers 62, where the metal structures 64 are configured to connect the active devices in the active layer 58 to each other (not shown) and/or configured to connect the active devices in the active layer 58 to corresponding redistribution interconnections 52 in the redistribution structure 40. In some applications, the BEOL portion 60 may also be configured to provide passive devices (e.g., utilizing the dielectric layers 62 and the metal structures 64 to form the passive devices, not shown).

When the thinned die 33 is an active die, the thinned die 33 may be formed from a silicon-on-insulator (SOI) structure. The active layer 58 of the thinned die 33 is formed by integrating active devices (not shown) in or on a silicon epitaxy layer of the SOI structure. The insulating layer 56 of the thinned die 33 is a buried oxide (i.e., silicon oxide, BOX) layer of the SOI structure. In addition, a silicon substrate of the SOI structure is removed substantially from the thinned die 33 (details described below). In some applications, a top surface of the thinned die 33 is a top surface of the insulating layer 56. The BEOL portion 60 is formed underneath the active layer 58 after the active layer 58 is completed.

In FIG. 2C, the thinned die 33 is a passive die, which includes the insulating layer 56 and the BEOL portion 60 underneath the insulating layer 56 without any active layer. In the BEOL portion 60, the dielectric layers 62 and the metal structures 64 are configured to provide one or more passive devices (e.g., resistors, capacitors, inductors, transmission lines, and any combination of them, etc., ). Some of the metal structures 64 are electrically connected to the corresponding redistribution interconnections 52 in the redistribution structure 40. In this embodiment, the thinned die 33 may be formed by an integrated passive device process, where the insulating layer 56 may be formed of one or more polymer materials (such as emulsion polymers, interlayer polymers or synthetic rubber) or one or more dielectric materials (such as silicon-dioxide, silicon-nitride, etc.).

Notice that, due to different types of the thinned dies 33, the corresponding intermediary mold compounds 44 might be formed of different materials with different characteristics. Each intermediary mold compound 44 may be formed of a same material as the mold compounds 42 (e.g., a standard molding material), formed of a high electric permittivity molding material (e.g., the electric permittivity >10, such as a molding material containing alumina and/or barium titanate), a high thermal conductivity molding material (e.g., the thermal conductivity >50 W/mK, such as a molding material having graphene added or a molding material having graphene alumina filler added), or a high magnetic permeability material (e.g., the magnetic permeability >50, such as a molding material with added powder containing iron, nickel, cobalt or a molding material with added powder containing ferri/ferro-magnetic materials, like magnetite, Ytrium-Iron-G, etc.). A standard molding compound with silica fillers has a low thermal conductivity around 1 W/mK. Using added graphene to alumina compounds, the thermal conductivity can be increased above 5 W/mK or even above 10 W/mK.

In addition, regardless of the types of the thinned dies 33, each thinned die 33 has substantially no substrate (e.g. no silicon substrate) and may have a thickness between few micrometers and several tens of micrometers. Each intermediary mold compound 44 may have a thickness between few micrometers and several tens of micrometers. A combination of one thinned die 33 and its corresponding intermediary mold compound 44 (i.e., one die section 38) may have a thickness between few micrometers and several tens of micrometers, or up to 100 micrometers, or up to 150 micrometers. Each redistribution structure 40 may have a thickness between 5 micrometers and few tens of micrometers.

Each package level 32 may have a thickness between few micrometers and several tens of micrometers, or up to 100 micrometers, or up to 150 micrometers (depending on thicknesses of the redistribution interconnections 52 and the dielectric pattern 50 in the redistribution structure 40). If high current capability is needed, thicker redistribution interconnections 52 need to be used. The bump structures 34 may have a height between several micrometers and few hundreds of micrometers (today's micro-bumps can get as low as 10 micrometers and may go below 10 micrometers). The top protection structure 36 may have a thickness between several tens of micrometers and about 200 micrometers, and the metal shield 54 may have a thickness between fractions of a micrometer and few micrometers. As such, the multi-level 3D package 30 with the vertically stacked thinned dies 33 can easily meet the low-profile requirements for the modern mobile assemblies at 0.8 mm, 0.65 mm or 0.5 mm. The multi-level 3D package 30 may accommodate a relatively large number of package levels 32/thinned dies 33 (e.g. four or more) stacked vertically.

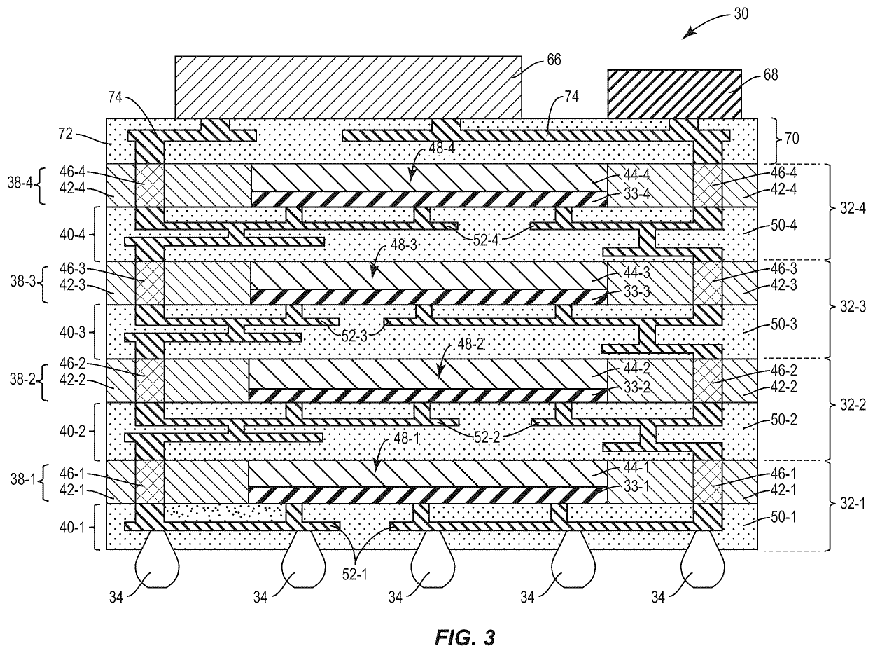

In some applications, the multi-level 3D package 30 may further include one or more components, which, unlike the thinned dies 33, cannot be reduced in height (details of die height reduction are described below), such as gallium arsenide (GaAs) dies, complementary metal-oxide-semiconductor (CMOS) dies, and surface mounted devices (SMDs). As illustrated in FIG. 3, the multi-level 3D package 30 further includes a first un-thinned component 66 and a second un-thinned component 68 at a top of the multi-level 3D package 30. To accommodate the first and second un-thinned dies 66 and 68, and to electrically connect the first and second un-thinned dies 66 and 68 to the thinned die(s) 33, the multi-level 3D package 30 includes a top redistribution structure 70 instead of the top protection structure 36 over the fourth package level 32-4. Herein, the top redistribution structure 70 includes a top dielectric pattern 72 and a number of top redistribution interconnections 74 within the top dielectric pattern 72. The top redistribution interconnections 74 are configured to connect the first un-thinned die 66 with the second un-thinned die 68 and/or connect the first/second un-thinned die 66/68 with the thinned die(s) 33 (e.g., the fourth thinned die 33-4) through one or more vertical via structures 46 (e.g., the fourth via structures 46-4).

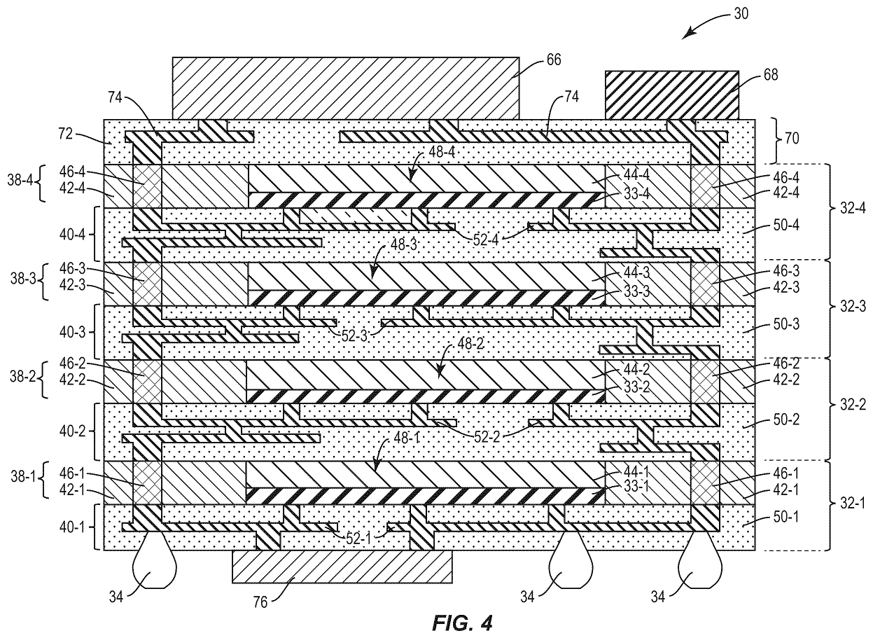

In some applications, the multi-level 3D package 30 may further include one or more un-thinned components at a bottom of the multi-level 3D package 30. As illustrated in FIG. 4, a third un-thinned component 76 is deposed underneath the first redistribution structure 40-1 and separate from the bump structures 34. In different applications, there might be multiple un-thinned components deposed underneath the first redistribution structure 40-1. The first redistribution interconnections 52-1 of the first redistribution structure 40-1 are further configured to connect the third un-thinned component 76 to the first thinned die 33-1, configured to connect the third un-thinned component 76 to some of the bump structures 34, and/or configured to connect the third un-thinned component 76 to one or more of the first vertical via structures 46-1. The third un-thinned component 76 might be a GaAs die, a CMOS die, or an SMD. For electrical and mechanical requirements of the multi-level 3D package 30, the third un-thinned component 76 needs to be shorter than the bump structures 34. As such, the third un-thinned component 76 will not further increase the height of the multi-level 3D package 30.

In some applications, the multi-level 3D package 30 may include a different number of thinned dies 33 in different die sections 38, as illustrated in FIGS. 5A-5E. FIG. 5A illustrates a cross-section view of the entire multi-level 3D package 30 along a dashed-line S-S′ at each die section 38, and FIGS. 5B˜5E illustrate a layout view of the thinned die(s) 33 at each die section 38. For the purpose of this illustration, the first die section 38-1 includes five first thinned dies 33-1 (i.e., a first thinned die A 33-1A, a first thinned die B 33-1B, a first thinned die C 33-1C, a first thinned die D 33-1D and a first thinned die E 33-1E); the second die section 38-2 includes four second thinned dies 33-2 (i.e., a second thinned die A 33-2A, a second thinned die B 33-2B, a second thinned die C 33-2C, and a second thinned die D 33-2D); the third die section 38-3 includes only one third thinned die 33-3; and the fourth die section 38-4 includes three fourth thinned dies 33-4 (i.e., a fourth thinned die A 33-4A, a fourth thinned die B 33-4B, and a fourth thinned die C 33-4C). Accordingly, the first die section 38-1 includes five first intermediary mold compounds 44-1 (i.e., a first intermediary mold compound A 44-1A, a first intermediary mold compound B 44-1B, a first intermediary mold compound C 44-1C, a first intermediary mold compound D 44-1D and a first intermediary mold compound E 44-1E); the second die section 38-2 includes four second intermediary mold compounds 44-2 (i.e., a second intermediary mold compound A 44-2A, a second intermediary mold compound B 44-2B, a second intermediary mold compound C 44-2C, and a second intermediary mold compound D 44-2D); the third die section 38-3 includes only one third intermediary mold compound 44-3; and the fourth die section 38-4 includes three fourth intermediary mold compounds 44-4 (i.e., a fourth intermediary mold compound A 44-4A, a fourth intermediary mold compound B 44-4B, and a fourth intermediary mold compound C 44-4C). In different applications, each die section 38 may include fewer or more thinned dies 33/intermediary mold compounds 44 with different layouts.

In one embodiment, each die section 38 may achieve different functionalities. For instance, the first die section 38-1 may achieve a receiver functionality, while the second die section 38-2 may achieve a transmitter functionality. In such case, the second redistribution structure 40-2 (between the first die section 38-1 and the second die section 38-2) may include an isolation metal shield (not shown), which is implemented by the second redistribution interconnections 52-2, to isolate signals in the first and second die sections 38-1 and 38-2. In one embodiment, each die section 38 may only include one or more specific types of dies. For instance, in the first die section 38-1, the first thinned dies 33-1 are all switch dies and/or LNA dies, while in the second die section 38-2, the second thinned dies 33-2 are all filter dies.

For electrical and mechanical requirements of the multi-level 3D package 30, each die section 38 must have a planarized top surface and a planarized bottom surface. In other words, in one die section 38, the thinned dies 33 may have different thicknesses, but a combination of each thinned die 33 and its corresponding intermediary mold compound 44 will have a same thickness. Also, in each die section 38, the mold compound 42 has a same thickness as the combination of each thinned die 33 and its corresponding intermediary mold compound 44.

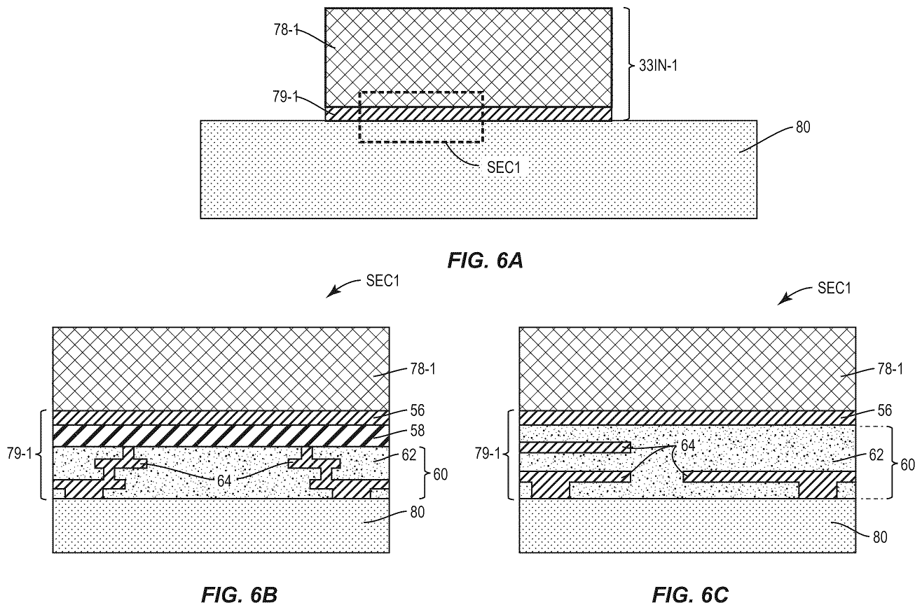

FIGS. 6A-36 provide exemplary steps to fabricate the exemplary multi-level 3D package 30 shown in FIG. 2A. Although the exemplary steps are illustrated in a series, the exemplary steps are not necessarily order dependent. Some steps may be done in a different order than that presented. Further, processes within the scope of this disclosure may include fewer or more steps than those illustrated in FIGS. 6A-36.

With reference to FIGS. 6A through 13, the first die section 38-1 is formed according to one embodiment of the present disclosure. Initially, a first intact die 33 IN-1, which includes a first die substrate 78-1 and a first device region 79-1, is attached to a module carrier 80, as illustrated in FIG. 6A. The first device region 79-1 is underneath the first die substrate 78-1 and resides over the module carrier 80, such that a backside of the first die substrate 78-1 is a top surface of the first intact die 33 IN-1. The first die substrate 78-1 may be formed of low cost silicon materials with a thickness between 150 micrometers and 700 micrometers, while the first device region 79-1 is configured to provide active and/or passive devices with a thickness between several micrometers and several tens of micrometers. It will be clear to those skilled in the art that modifications to these thicknesses may also be considered within the scope of the concepts disclosed herein.

In one embodiment, the first intact die 33 IN-1 is an active die, where the first device region 79-1 includes the insulating layer 56, the active layer 58 underneath the insulating layer 56, and the BEOL portion 60 underneath the active layer 58, as illustrated in FIG. 6B (dashed box SEC1 in FIG. 6A). The active layer 58 is configured to provide one or more active devices (e.g., devices with one or more transistors, such as a power amplifier, a low-noise amplifier, and a switch), while the BEOL portion 60 is configured to connect the active devices in the active layer 58 to each other and/or configured to connect the active devices in the active layer 58 to external components (e.g., corresponding redistribution interconnections 52 in the redistribution structure 40, see FIG. 2B). Typically, the BEOL portion 60 includes the dielectric layers 62 and the metal structures 64 that realize the connection function of the BEOL 60. In some applications, the BEOL portion 60 may also be configured to provide passive devices (e.g., utilizing the dielectric layers 62 and the metal structures 64 to form resistors, capacitors, inductors, transmission lines, and any combination of them, etc., not shown).

When the first intact die 33 IN-1 is an active die, the first intact die 33 IN-1 may be formed from a SOI structure. The active layer 58 of the first intact die 33 IN-1 is formed by integrating active devices (not shown) in or on a silicon epitaxy layer of the SOI structure. The insulating layer 56 of the first intact die 33 IN-1 is a buried oxide (i.e., silicon oxide, BOX) layer of the SOI structure. In addition, the first die substrate 78-1 of the first intact die 33 IN-1 is a silicon substrate of the SOI structure. The BEOL portion 60 is formed underneath the active layer 58 after the active layer 58 is completed.

In one embodiment, the first intact die 33 IN-1 is a passive die, where the first device region 79-1 does not include any active layer but only includes the insulating layer 56 and the BEOL portion 60 underneath the insulating layer 56, as illustrated in FIG. 6C (dashed box SEC1 in FIG. 6A). In the BEOL portion 60, the dielectric layers 62 and the multi-layer metal structure 64 may be configured to provide one or more passive devices (e.g., resistors, capacitors, inductors, transmission lines, and any combination of them, etc.,). When the first intact die 33 IN-1 is a passive die, the first intact die 33 IN-1 may be formed by an integrated passive device process, where the insulating layer 56 of the first intact die 33 IN-1 may be formed of one or more polymer materials (such as emulsion polymers, interlayer polymers and synthetic rubbers) or one or more dielectric materials (such as silicon oxide, silicon nitride, etc.) and the first die substrate 78-1 of the first intact die 33 IN-1 is a silicon substrate.

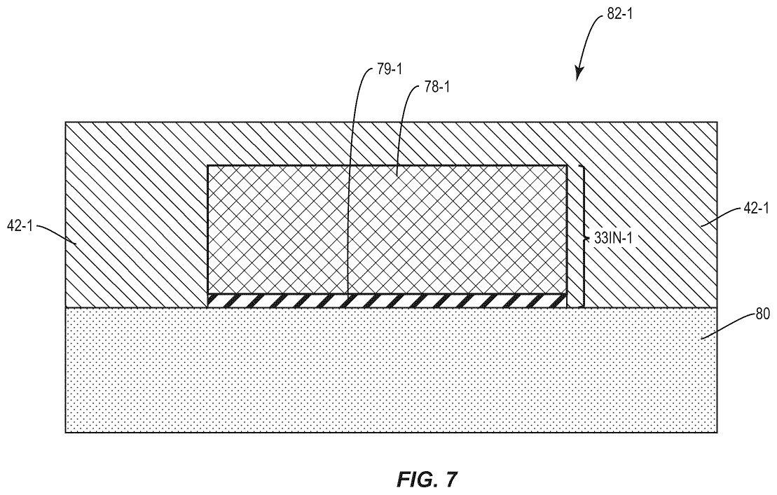

Next, the first mold compound 42-1 is applied over the module carrier 80 and fully encapsulates the first intact die 33 IN-1 to provide a first precursor 82-1, as illustrated in FIG. 7. The first mold compound 42-1 may be applied by various procedures, such as sheet molding, overmolding, compression molding, transfer molding, dam fill encapsulation, or screen print encapsulation. The first mold compound 42-1 may be formed of a standard molding material (e.g., an organic epoxy resin system or the like), which can be used as an etchant barrier to the first device region 79-1 of the first intact die 33 IN-1 against etching chemistries such as Tetramethylammonium hydroxide (TMAH), potassium hydroxide (KOH), sodium hydroxide (NaOH), and acetylcholine (ACH). A curing process (not shown) is then used to harden the first mold compound 42-1. The curing temperature is between 100° C. and 320° C. depending on which material is used as the first mold compound 42-1.

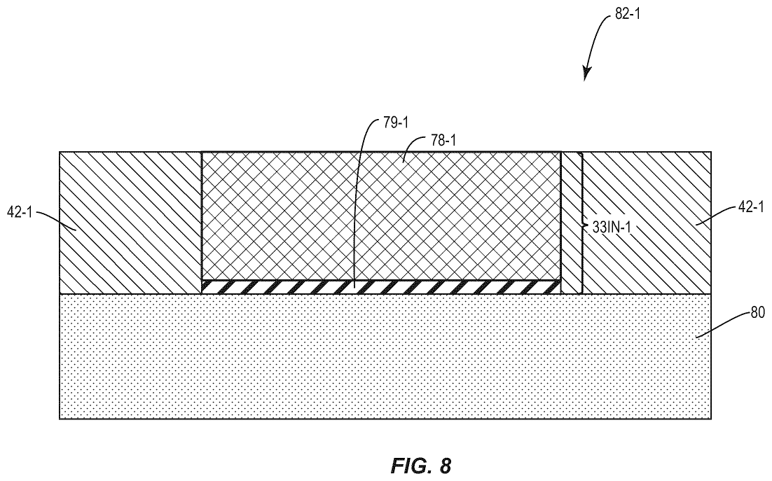

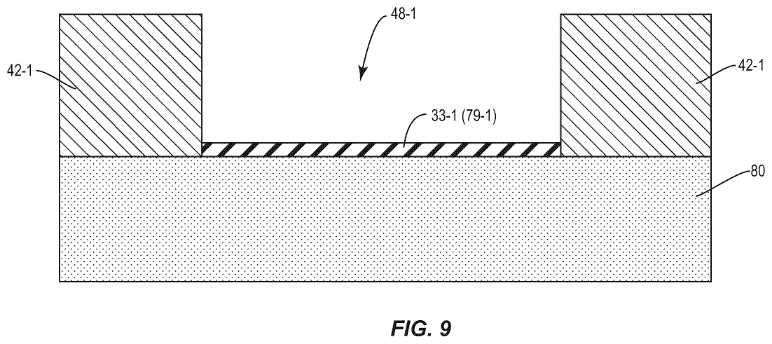

The first mold compound 42-1 is then thinned down to expose the backside of the first die substrate 78-1 of the first intact die 33 IN-1, as shown in FIG. 8. The thinning procedure may be done with a mechanical grinding process. The following step is to remove substantially the first die substrate 78-1 of the first intact die 33 IN-1 to provide the first thinned die 33-1 that includes the first device region 79-1 and define the first opening 48-1 over the first thinned die 33-1, as illustrated in FIG. 9. Herein, removing substantially the first die substrate 78-1 refers to removing at least 95% of the entire first die substrate 78-1, and leaving at most 2 micrometers die substrate or perhaps further removing a portion of the insulating layer 56. In desired cases, the first die substrate 78-1 is fully removed, such that the first thinned die 33-1 is the first device region 79-1, where the top surface of the insulating layer 56 is the top surface of the first thinned die 33-1 and is exposed at the bottom of the first opening 48-1. Removing substantially the first die substrate 78-1 may be provided by an etching process with a wet/dry etchant chemistry, which may be TMAH, KOH, NaOH, ACH, or the like. During the etching process, the insulating layer 56 functions as an etching stop layer, which has a much slower rate of being etched than the first die substrate 78-1 (i.e. silicon substrate) by using the wet/dry etchant chemistries. The first mold compound 42-1 may be used as an etchant barrier to protect at least sides of the first device region 79-1 against the etchant chemistries. Thus, the first opening 48-1, where the first die substrate 78-1 was removed, is defined within the first mold compound 42-1, and the vertical walls of the first opening 48-1 are inner sides of the first mold compound 42-1 that are aligned with the edges of the first thinned die 33-1.

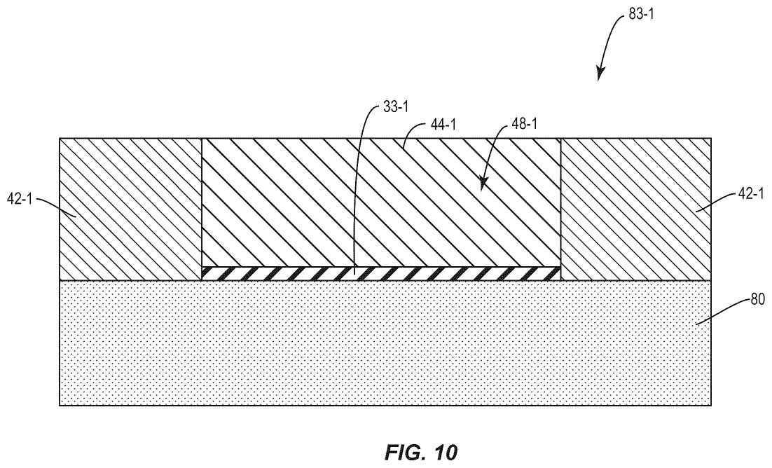

The first intermediary mold compound 44-1 is applied over the first thinned die 33-1 to provide a first molding precursor 83-1 as illustrated in FIG. 10. The first intermediary mold compound 44-1 substantially fills the first opening 48-1. The first intermediary mold compound 44-1 may be applied by various procedures, such as sheet molding, overmolding, compression molding, transfer molding, dam fill encapsulation, and screen print encapsulation. The first intermediary mold compound 44-1 directly resides over the top surface of the first thinned die 33-1. If there is no first die substrate 78-1 left in the first thinned die 33-1, the first intermediary mold compound 44-1 directly resides over the insulating layer 56. Due to a different type of the first thinned die 33-1, the first intermediary mold compound 44-1 might be formed of a different material with different characteristics. The first intermediary mold compound 44-1 may be formed of a same material as the first mold compound 42-1 (e.g., a standard molding material), formed of a high electric permittivity molding material (e.g., the electric permittivity >10, such as a molding material containing alumina and/or barium titanate), a high thermal conductivity molding material (e.g., the thermal conductivity >50 W/mK, such as a molding material having graphene added or a molding material having graphene and alumina filler added), or a high magnetic permeability material (e.g., the magnetic permeability >50, such as a molding material with added powder containing iron, nickel, cobalt or a molding material with added powder containing ferri/ferro-magnetic materials, like magnetite, Ytrium-Iron-G, etc.). A curing process (not shown) is followed to harden the first intermediary mold compound 44-1. The curing temperature is between 100° C. and 320° C. depending on which material is used as the first intermediary mold compound 44-1.

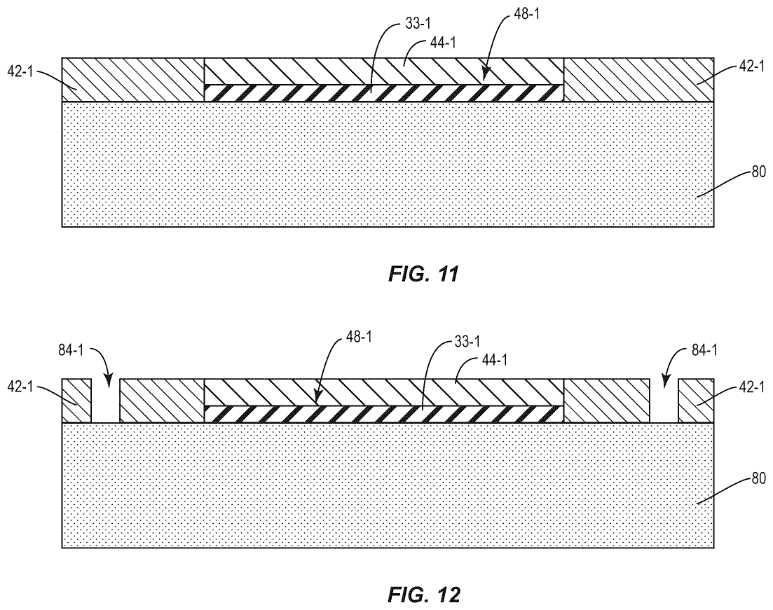

A polishing step is then applied to the first molding precursor 83-1 to determine a final thickness of the first mold compound 42-1 and a final thickness of the combination of the first thinned die 33-1 and the first intermediary mold compound 44-1 (i.e., a final thickness of the first die section 38-1). As illustrated in FIG. 11, the thickness of the first mold compound 42-1 and the thickness of the first intermediary mold compound 44-1 are reduced and the first opening 48-1 becomes shallower. The polishing step may be implemented by a mechanical grinding process. After the polishing step, the top surface of the first mold compound 42-1 is coplanar with the top surface of the first intermediary mold compound 44-1. The final thickness of the first mold compound 42-1 and the final thickness of the combination of the first thinned die 33-1 and the first intermediary mold compound 44-1 have a same value, between several micrometers and several tens of micrometers, or up to 100 micrometers, or up to 150 micrometers.

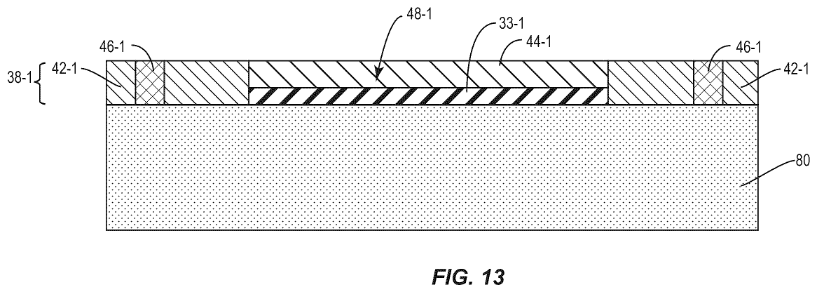

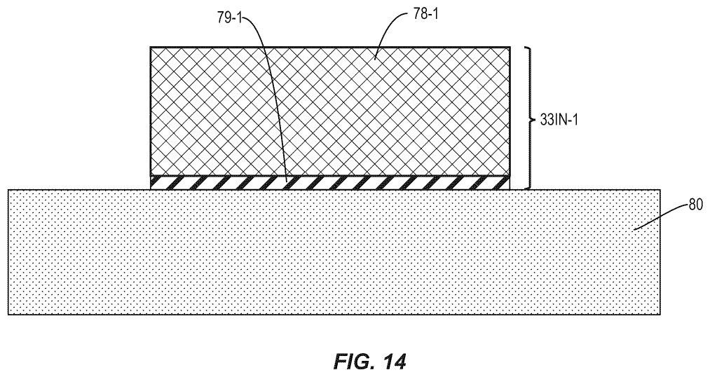

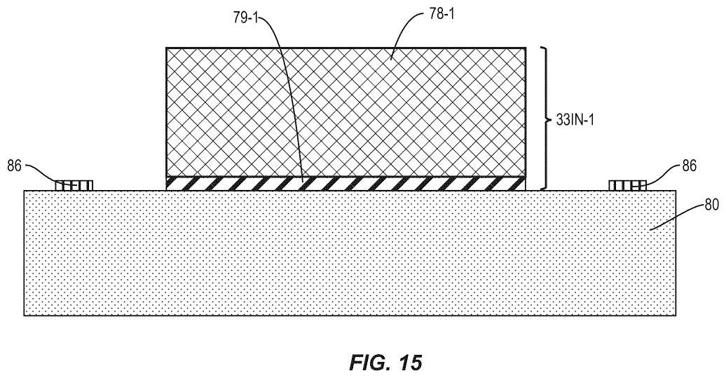

Next, first vertical via holes 84-1 are formed through the first mold compound 42-1, as illustrated in FIG. 12. The first vertical via holes 84-1 do not extend through or into the first thinned die 33-1 or the first intermediary mold compound 44-1. Each first vertical via hole 84-1 may have a shape of a cuboid, a polygon, a cylinder, or a cone and has a depth the same as the thickness of the first mold compound 42-1. The first vertical via holes 84-1 may be formed by a drilling process. The first vertical via structures 46-1 are then formed in the first vertical via holes 84-1 to complete the first die section 38-1, as illustrated in FIG. 13. The first vertical via structures 46-1 may be formed by filling the first vertical via holes 84-1 with one or more appropriate materials. The appropriate material is required to be electrically and/or thermally conductive, such as platinum, gold, silver, copper, aluminum, tungsten, titanium, electrically conductive epoxy, or other suitable materials. The top surface of the first mold compound 42-1, the top surface of the first intermediary mold compound 44-1, and a top surface of each first vertical via structure 46-1 are coplanar. The thickness of the first die section 38-1 is between several micrometers and several tens of micrometers. In some cases, the first die section 38-1 may have a larger thickness, for instance, up to 100 micrometers or even up to 150 micrometers. FIGS. 14-21 illustrate an alternative process to form the first die section 38-1 according to one embodiment of the present disclosure. Similarly, the first intact die 33 IN-1, which includes the first die substrate 78-1 and the first device region 79-1 underneath the first die substrate 78-1, is firstly attached to the module carrier 80, as illustrated in FIG. 14. Seed layers 86 are then deposited over the module carrier 80 and around the first intact die 33 IN-1, as illustrated in FIG. 15. For Electro-Chemical-Plating (ECP), the seed layers 86 need to have a low conformality. For example, a tantalum barrier layer can be used as the seed layer 86 for electroplating/electro-chemical-plating (EP or ECP) of copper in a forward pulsed mode. The conformal seed layers 86 provides a base for the first plated vertical via structures 46-1. The seed layers 86 may be formed by many types of processes, including metal organic chemical vapor deposition (MOCVD), Physical Vapor Deposition PVD and long throw sputtering (LTS).

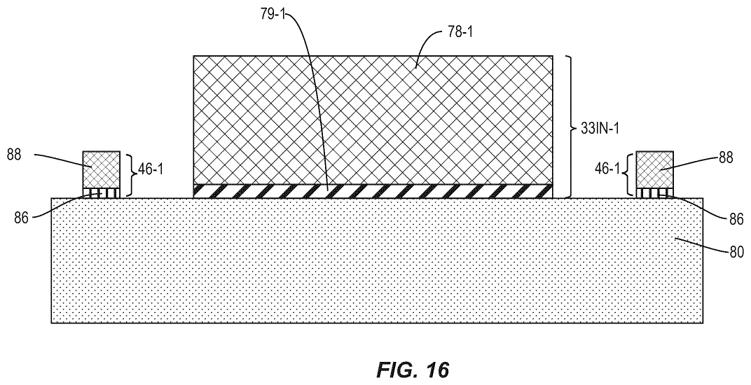

Next, one or more metal/alloy materials 88 (such as copper, aluminum silver, and gold) are plated over each seed layer 86 to form one first vertical via structure 46-1, as illustrated in FIG. 16. Notice that the height of each first vertical via structures 46-1 must be carefully selected as the final thickness of the first die section 38-1/the final thickness of the first mold compound 42-1, such that each first vertical via structures 46-1 can be exposed through the first mold compound 42-1 once the first die section 38-1 is completed. Each first vertical via structure 46-1 has a same height between several micrometers and several tens of micrometers, up to 100 micrometers, or up to 150 micrometers. Each first vertical via structure 46-1 is always shorter than the first intact die 33 IN-1, and is always taller than the first device region 79-1 of the first intact die 33 IN-1.

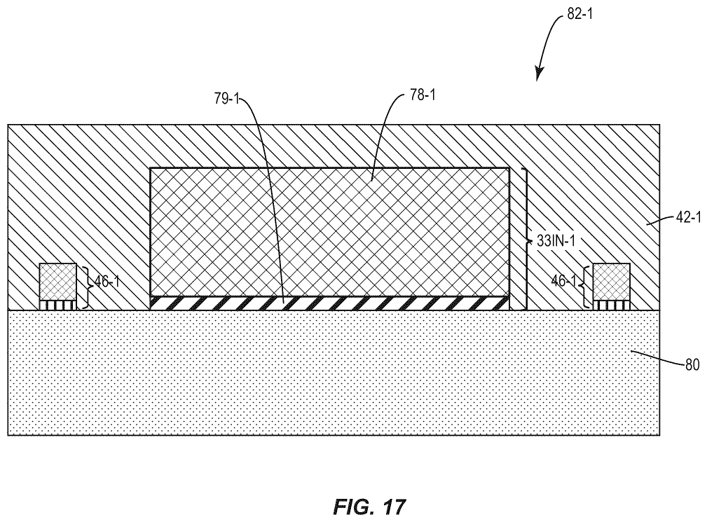

The first mold compound 42-1 is then applied over the module carrier 80 and fully encapsulate the first intact die 33 IN-1 and fully encapsulates each first vertical via structure 46-1 to provide the first precursor 82-1, as illustrated in FIG. 17. The first mold compound 42-1 may be applied by various procedures, such as sheet molding, overmolding, compression molding, transfer molding, dam fill encapsulation, or screen print encapsulation. The first mold compound 42-1 may be formed of a standard molding material (e.g., an organic epoxy resin system or the like), which can be used as an etchant barrier to the first device region 79-1 of the first intact die 33 IN-1 against etching chemistries such as TMAH, KOH, NaOH, and ACH. A curing process (not shown) is then used to harden the first mold compound 42-1. The curing temperature is between 100° C. and 320° C. depending on which material is used as the first mold compound 42-1.

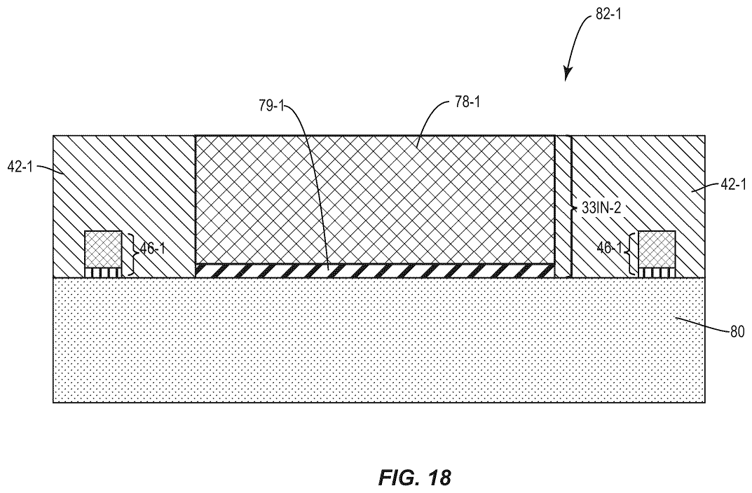

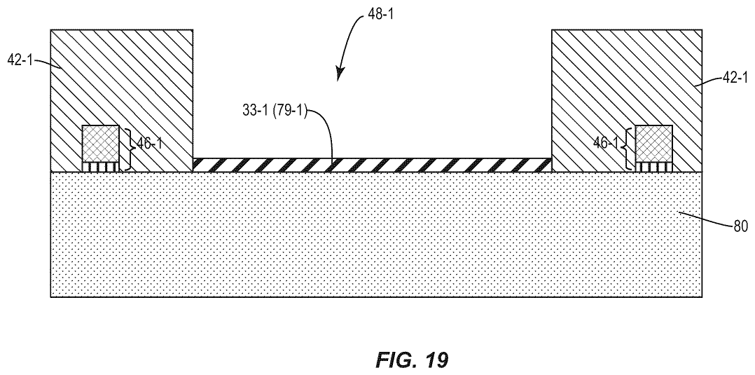

After the first mold compound 42-1 is applied, the first mold compound 42-1 is thinned down to expose the backside of the first die substrate 78-1 of the first intact die 33 IN-1, as shown in FIG. 18. Since each first vertical via structure 46-1 is shorter than the first intact die 33 IN-1, each first vertical via structure 46-1 is still fully encapsulated by the first mold compound 42-1. The thinning procedure may be done with a mechanical grinding process. Since each first vertical via structure 46-1 is shorter than the first intact die 33 IN-1, each first vertical via structure 46-1 is still fully encapsulated by the first mold compound 42-1. The following step is to remove substantially the first die substrate 78-1 of the first intact die 33 IN-1 to provide the first thinned die 33-1 that includes the first device region 79-1 and define the first opening 48-1 over the first thinned die 33-1, as illustrated in FIG. 19. Herein, removing substantially the first die substrate 78-1 refers to removing at least 95% of the entire first die substrate 78-1, and leaving at most 2 micrometers die substrate or perhaps further removing a portion of the insulating layer 56. In desired cases, the first die substrate 78-1 is fully removed, such that the first thinned die 33-1 is the first device region 79-1, where the top surface of the insulating layer 56 is the top surface of the first thinned die 33-1 and is exposed at the bottom of the first opening 48-1 (see FIGS. 6B and 6C). Removing substantially the first die substrate 78-1 may be provided by an etching process with a wet/dry etchant chemistry, which may be TMAH, KOH, NaOH, ACH, or the like. During the etching process, the insulating layer 56 functions as an etching stop layer, which has a much slower rate of being etched than the first die substrate 78-1 (i.e. silicon substrate) by using the wet/dry etchant chemistries. The first mold compound 42-1 may be used as an etchant barrier to protect at least sides of the first device region 79-1 against the etchant chemistries. Thus, the first opening 48-1, where the first die substrate 78-1 was removed, is defined within the first mold compound 42-1, and the vertical walls of the first opening 48-1 are inner sides of the first mold compound 42-1 that are aligned with the edges of the first thinned die 33-1.

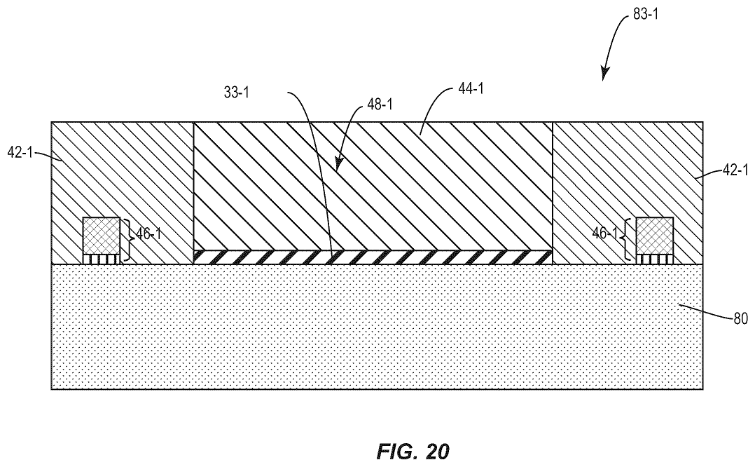

Next, the first intermediary mold compound 44-1 is applied over the first thinned die 33-1 to provide the first molding precursor 83-1 as illustrated in FIG. 20. The first intermediary mold compound 44-1 substantially fills the first opening 48-1. The first intermediary mold compound 44-1 may be applied by various procedures, such as sheet molding, overmolding, compression molding, transfer molding, dam fill encapsulation, and screen print encapsulation. The first intermediary mold compound 44-1 directly resides over the top surface of the first thinned die 33-1. If there is no first die substrate 78-1 left in the first thinned die 33-1, the first intermediary mold compound 44-1 directly resides over the insulating layer 56. A curing process (not shown) is followed to harden the first intermediary mold compound 44-1. The curing temperature is between 100° C. and 320° C. depending on which material is used as the first intermediary mold compound 44-1.

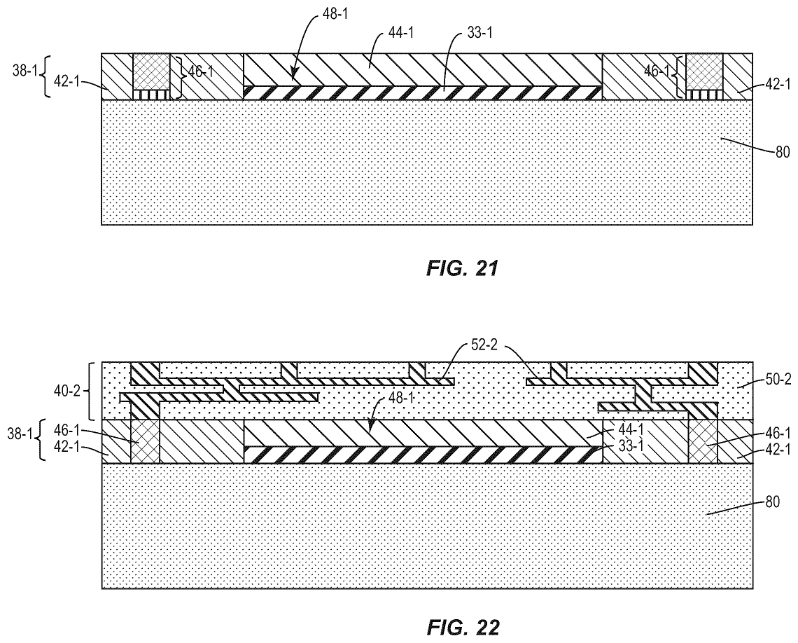

A polishing step is then applied to the first molding precursor 83-1 to provide the first die section 38-1. As illustrated in FIG. 21, the thickness of the first intermediary mold compound 44-1 and the thickness of the first mold compound 42-1 are reduced until each first vertical via structure 46-1 is exposed through the first mold compound 42-1. The polishing step may be implemented by a mechanical grinding process. After the polishing step, the top surface of the first mold compound 42-1, the top surface of the first intermediary mold compound 44-1, and a top surface of each first vertical via structure 46-1 are coplanar.

After the first die section 38-1 is formed, the second redistribution structure 40-2 is formed over the first die section 38-1, as illustrated in FIG. 22. The second redistribution structure 40-2 includes the second dielectric pattern 50-2 and the second redistribution interconnections 52-2 within the second dielectric pattern 50-2. Herein, some portions of the second redistribution interconnections 52-2 are exposed through the second dielectric pattern 50-2 at the bottom of the second redistribution structure 40-2, and are connected to the first vertical via structures 46-1 in the first die section 38-1. In addition, some other portions of the second redistribution interconnections 52-2 are exposed through the second dielectric pattern 50-2 at the top of the second redistribution structure 40-2.

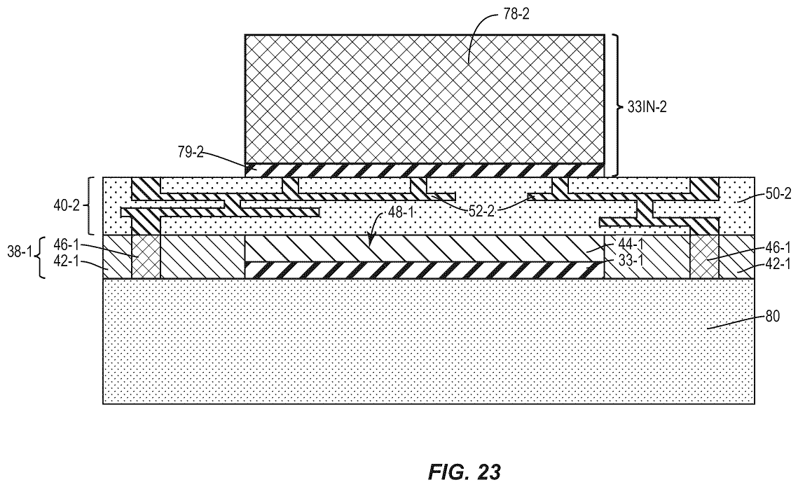

A second intact die 33 IN-2, which includes a second die substrate 78-2 and a second device region 79-2, is attached to the second redistribution structure 40-2, as illustrated in FIG. 23. The second device region 79-2 is underneath the second die substrate 78-2 and resides over the second redistribution structure 40-2. As such, the second device region 79-2 is connected to some of the exposed portions of the second redistribution interconnections 52-2 at the top of the second redistribution structure 40-2, and a backside of the second die substrate 78-2 is a top surface of the second intact die 33 IN-2. Similar to the first intact die 33 IN-1, the second die substrate 78-2 in the second intact die 33 IN-2 may be formed of low cost silicon materials with a thickness between 150 micrometers and 700 micrometers, while the second device region 79-2 in the second intact die 33 IN-2 is configured to provide active and/or passive devices with a thickness between several micrometers to several tens of micrometers. The second device region 79-2 may have a similar structure as the first device region 79-1 as shown in FIG. 6B (e.g., including the insulating layer 56, the active layer 58 underneath the insulating layer 56, and the BEOL portion 60, which has the dielectric layers 62 and the metal structures 64 within the dielectric layers 62, underneath the active layer 58) or FIG. 6C (e.g., including the insulating layer 56, and the BEOL portion 60, which has the dielectric layers 62 and the metal structures 64 within the dielectric layers 62, underneath the insulating layer 56). It will be clear to those skilled in the art that modifications to these thicknesses may also be considered within the scope of the concepts disclosed herein.

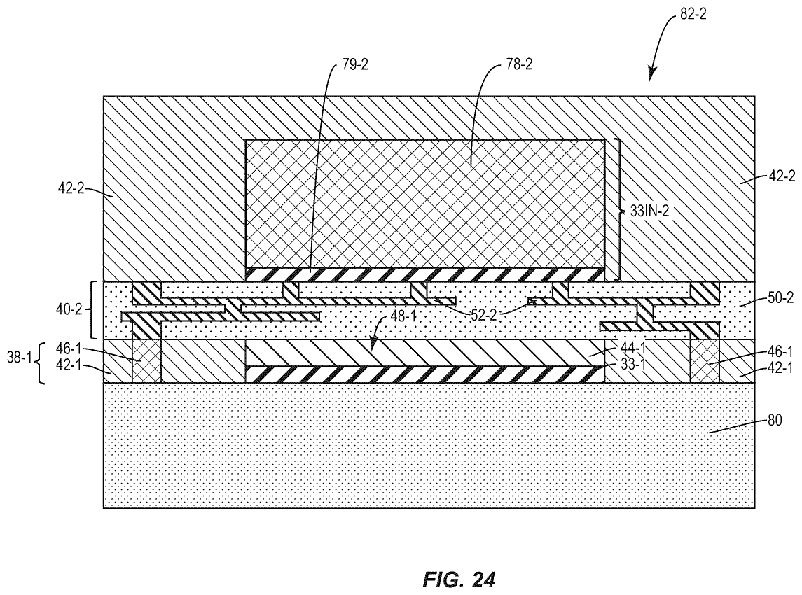

Next, the second mold compound 42-2 is applied over a top surface of the second redistribution structure 40-2 and fully encapsulates the second intact die 33 IN-2 to provide a second precursor 82-2, as illustrated in FIG. 24. The second mold compound 42-2 may be applied by various procedures, such as sheet molding, overmolding, compression molding, transfer molding, dam fill encapsulation, or screen print encapsulation. The second mold compound 42-2 may be formed of a standard molding material (e.g., an organic epoxy resin system or the like), which can be used as an etchant barrier to the second device region 79-2 of the second intact die 33 IN-2 against etching chemistries such as TMAH, KOH, NaOH, and ACH. A curing process (not shown) is then used to harden the second mold compound 42-2. The curing temperature is between 100° C. and 320° C. depending on which material is used as the second mold compound 42-2.

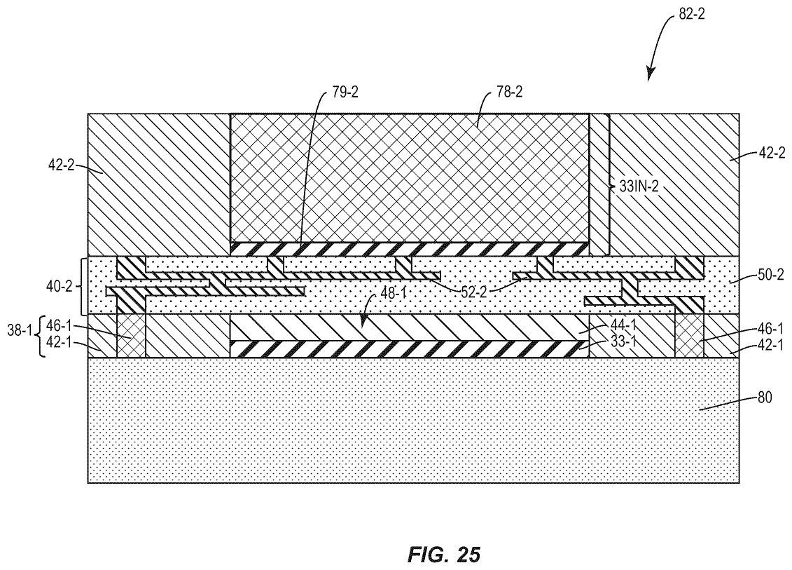

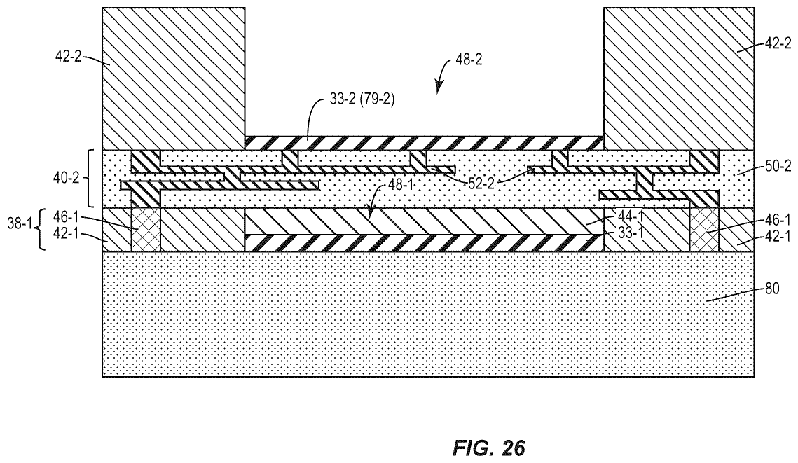

The second mold compound 42-2 is then thinned down to expose the backside of the second die substrate 78-2 of the second intact die 33 IN-2, as shown in FIG. 25. The thinning procedure may be done with a mechanical grinding process. The following step is to remove substantially the second die substrate 78-2 of the second intact die 33 IN-2 to provide the second thinned die 33-2 that includes the second device region 79-2 and define the second opening 48-2 over the second thinned die 33-2, as illustrated in FIG. 26. Herein, removing substantially the second die substrate 78-2 refers to removing at least 95% of the entire second die substrate 78-2, and leaving at most 2 micrometers die substrate or perhaps further removing a portion of the insulating layer 56 (see FIGS. 6B and 6C). In desired cases, the second die substrate 78-2 is fully removed, such that the second thinned die 33-2 is the second device region 79-2, where the top surface of the insulating layer 56 is the top surface of the second thinned die 33-2 and is exposed at the bottom of the second opening 48-2. Removing substantially the second die substrate 78-2 may be provided by an etching process with a wet/dry etchant chemistry, which may be TMAH, KOH, NaOH, ACH, or the like. During the etching process, the insulating layer 56 functions as an etching stop layer, which has a much slower rate of being etched than the second die substrate 78-2 (i.e., silicon substrate) by using the wet/dry etchant chemistries. The second mold compound 42-2 may be used as an etchant barrier to protect at least sides of the second device region 79-2 against the etchant chemistries. Thus, the second opening 48-2, where the second die substrate 78-2 was removed, is defined within the second mold compound 42-2, and the vertical walls of the second opening 48-2 are inner sides of the second mold compound 42-2 that are aligned with the edges of the second thinned die 33-2.

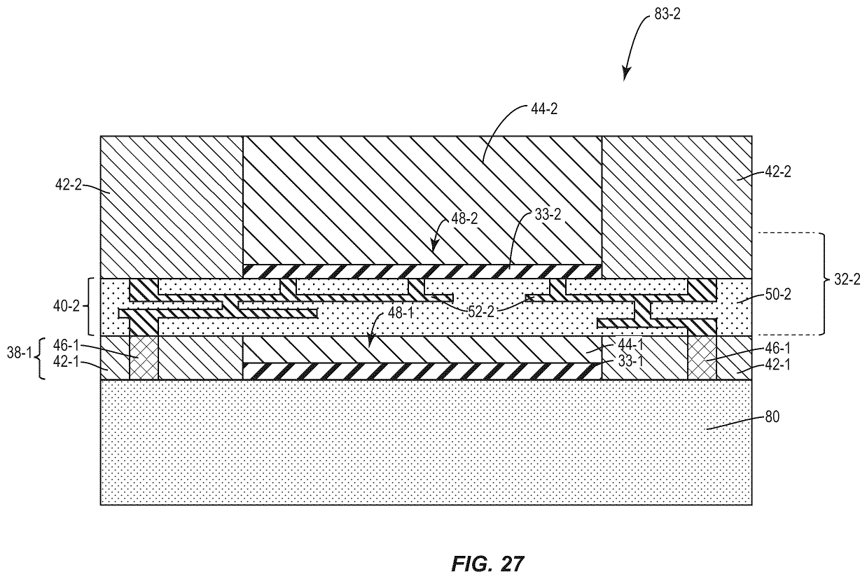

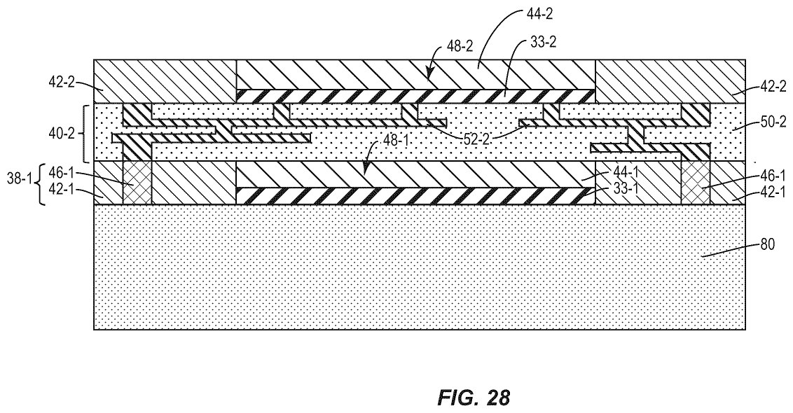

The second intermediary mold compound 44-2 is applied over the second thinned die 33-2 to provide a second molding precursor 83-2, as illustrated in FIG. 27. The second intermediary mold compound 44-2 substantially fills the second opening 48-2. The second intermediary mold compound 44-2 may be applied by various procedures, such as sheet molding, overmolding, compression molding, transfer molding, dam fill encapsulation, and screen print encapsulation. The second intermediary mold compound 44-2 directly resides over the top surface of the second thinned die 33-2. If there is no second die substrate 78-2 left in the second thinned die 33-2, the second intermediary mold compound 44-2 directly resides over the insulating layer 56. Due to a different type of the second thinned die 33-2, the second intermediary mold compound 44-2 might be formed of a different material with different characteristics. The second intermediary mold compound 44-2 may be formed of a same material as the second mold compound 42-2 (e.g., a standard molding material), formed of a high electric permittivity molding material (e.g., the electric permittivity >10, such as a molding material containing alumina and/or barium titanate), a high thermal conductivity molding material (e.g., the thermal conductivity >50 W/mK, such as a molding material having graphene added or a molding material having graphene and alumina filler added), or a high magnetic permeability material (e.g., the magnetic permeability >50, such as a molding material with added powder containing iron, nickel, cobalt or a molding material with added powder containing ferri/ferro-magnetic materials, like magnetite, Ytrium-Iron-G, etc.). Notice that the second thinned die 33-2 and the first thinned die 33-1 may be a same type or different types, and the second intermediary mold compound 44-2 and the first intermediary mold compound 44-1 may be formed of a same material or different materials. A curing process (not shown) is followed to harden the second intermediary mold compound 44-2. The curing temperature is between 100° C. and 320° C. depending on which material is used as the second intermediary mold compound 44-2.

A polishing step is followed to determine a final thickness of the second mold compound 42-2 and a final thickness of the combination of the second thinned die 33-2 and the second intermediary mold compound 44-2 (i.e., a final thickness of the second die section 38-2). As illustrated in FIG. 28, the thickness of the second mold compound 42-2 and the thickness of the second intermediary mold compound 44-2 are reduced and the second opening 48-2 becomes shallower. The polishing step may be implemented by a mechanical grinding process. After the polishing step, the top surface of the second mold compound 42-2 is coplanar with the top surface of the second intermediary mold compound 44-2. The final thickness of the second mold compound 42-2 and the final thickness of the combination of the second thinned die 33-2 and the second intermediary mold compound 44-2 have a same value, between several micrometers and several tens of micrometers, or up to 100 micrometers, or up to 150 micrometers.

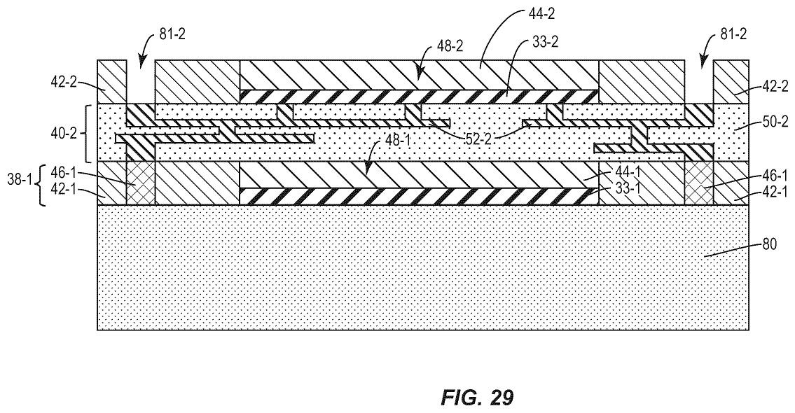

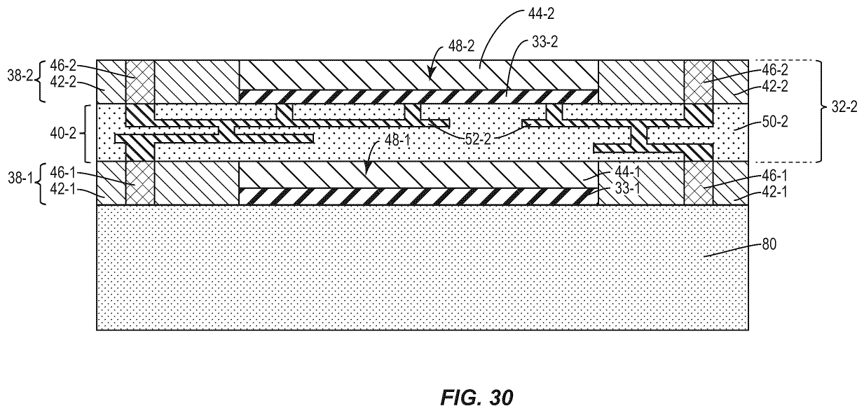

Next, second vertical via holes 84-2 are formed through the second mold compound 42-1 to reveal some portions of the second redistribution interconnections 52-2 exposed at the top of the second redistribution structure 40-2, as illustrated in FIG. 29. The second vertical via holes 84-2 do not extend through or into the second thinned die 33-2 or the second intermediary mold compound 44-2. Each second vertical via hole 84-2 may have a shape of a cuboid, a polygon, a cylinder, or a cone and has a depth the same as the thickness of the second mold compound 42-2. The second vertical via holes 84-2 may be formed by a drilling process. The second vertical via structures 46-2 are then formed in the second vertical via holes 84-2 to complete the second die section 38-2 as well as the second package level 32-2 (including the second die section 38-1 and the second redistribution structure 40-2), as illustrated in FIG. 30. The second vertical via structures 46-2 may be formed by filling the second vertical via holes 84-2 with one or more appropriate materials. The appropriate material is required to be electrically and/or thermally conductive, such as platinum, gold, silver, copper, aluminum, tungsten, titanium, electrically conductive epoxy, or other suitable materials. The top surface of the second mold compound 42-2, the top surface of the second intermediary mold compound 44-2, and a top surface of each second vertical via structure 46-2 are coplanar.

In some applications, the second die section 38-2 may be formed in a similar process as shown in FIGS. 14-21. The only differences are that the second intact die 33 IN-2 is not attached to the module carrier 80 but the top surface of the second redistribution structure 40-2; the seed layers 86 is not deposited on the module carrier 80 but deposited on some portions of the second redistribution interconnections 52-2 exposed at the top of the second redistribution structure 40-2; and the second mold compound 42-2 is not applied over the module carrier 80 but applied over the top surface of the second redistribution structure 40-2 (not shown).

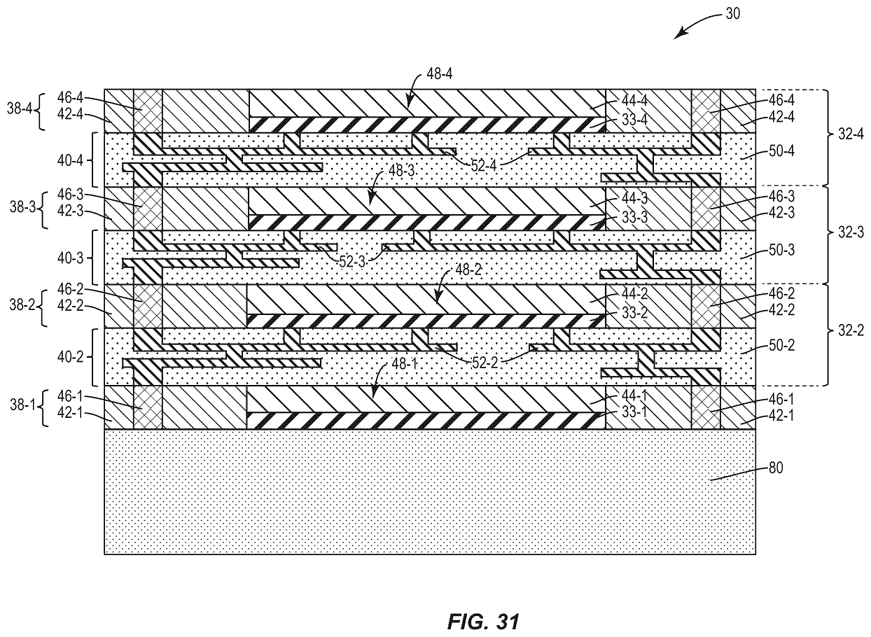

The third and fourth package levels 32-3 and 32-4 are formed using the same processing steps as the second package level 32-2 (e.g. as illustrated in FIGS. 22-30). The third package level 32-3 is formed over the second package level 32-2, and the fourth package level 32-4 is formed over the third package level 32-3, as illustrated in FIG. 31. As such, the first, second, third, and fourth thinned dies 33-1˜33-4 are vertically stacked.

Notice that, in different applications, there might be more package levels 32 included in the multi-level 3D package 30. Of course, the larger thickness of each package level, the less numbers of package levels can be vertically stacked. In addition, in different applications, there might be multiple thinned dies 33 included in one or more package levels 32. Each thinned die 33 included in any package level 32 may be formed from one intact die 33 IN with the silicon substrate 78, which can be substantially removed. Components without silicon substrate, such as GaAs dies, CMOS dies, and/or SMDs, cannot be intact dies because their height cannot be reduced. Furthermore, these components without silicon substrate, which typically has a height between 100 micrometers and several hundreds of micrometers, may not be included in any package level 32. In addition, each redistribution structure 40 is formed at a wafer level, and each polishing step to reduce the thickness of the mold compound 42 and the thickness of the intermediary mold compound 44 is performed at a wafer level.

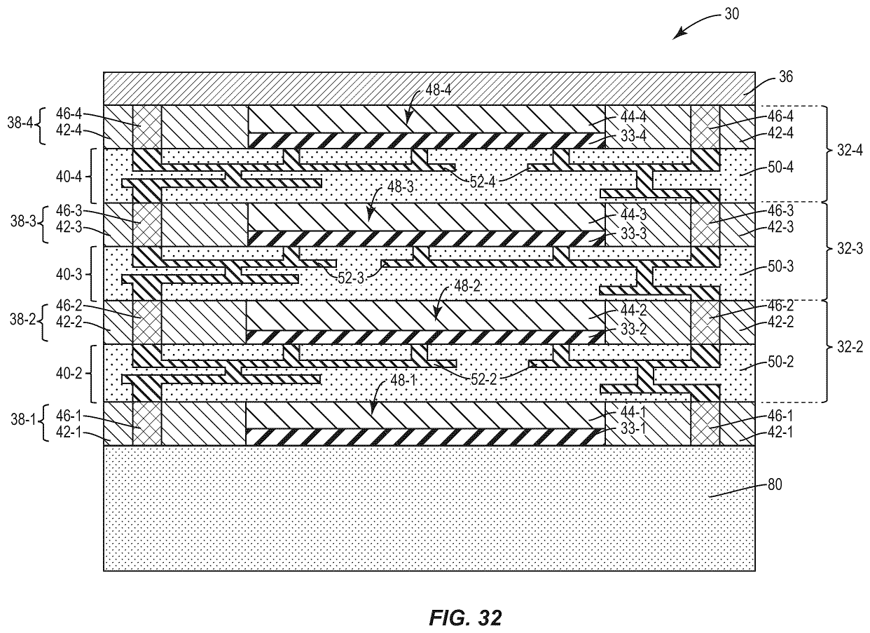

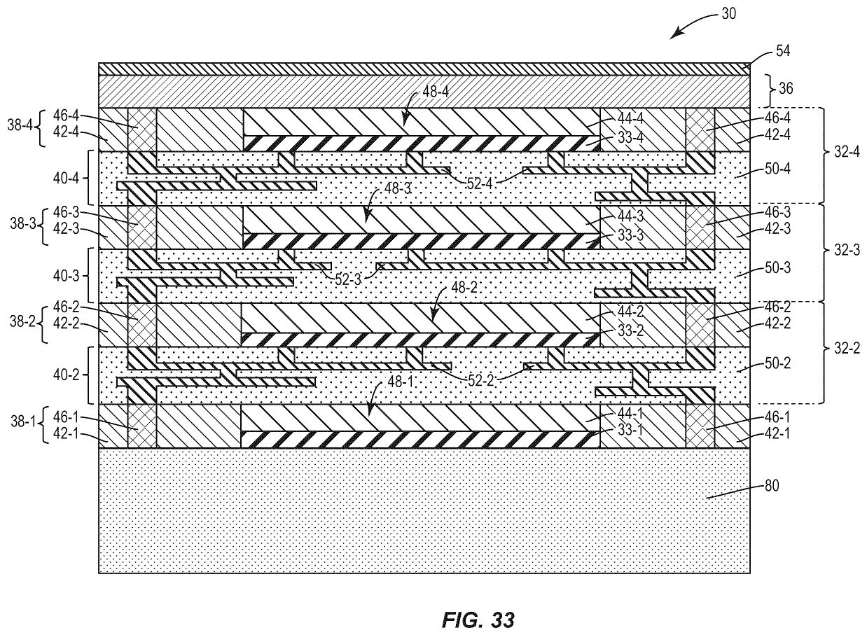

In one embodiment, the top protection structure 36 is then formed over the fourth die section 38-4 of the fourth package level 32-4 (i.e., over the fourth mold compound 42-4 and the fourth intermediary mold compound 44-4) and coupled to the fourth vertical via structures 46-4, as illustrated in FIG. 32. The top protection structure 36 may be formed of molding materials and optionally one or more glass-type materials for final sealing at the top of the top protection structure 36. The top protection structure 36 is configured to provide chemical and gas/air contamination protection. The top protection structure 36 may have a thickness between several tens of micrometers and about 200 micrometers. In addition, the metal shield 54 may be applied over the top protection structure 36, as illustrated in FIG. 33. The metal shield 54 may be formed of copper, aluminum or other metals or alloys by a plating, sputtering or spraying process. The metal shield 54 is configured to provide electro-magnetic shielding. The metal shield 54 may have a thickness between fractions of a micrometers and few micrometers.

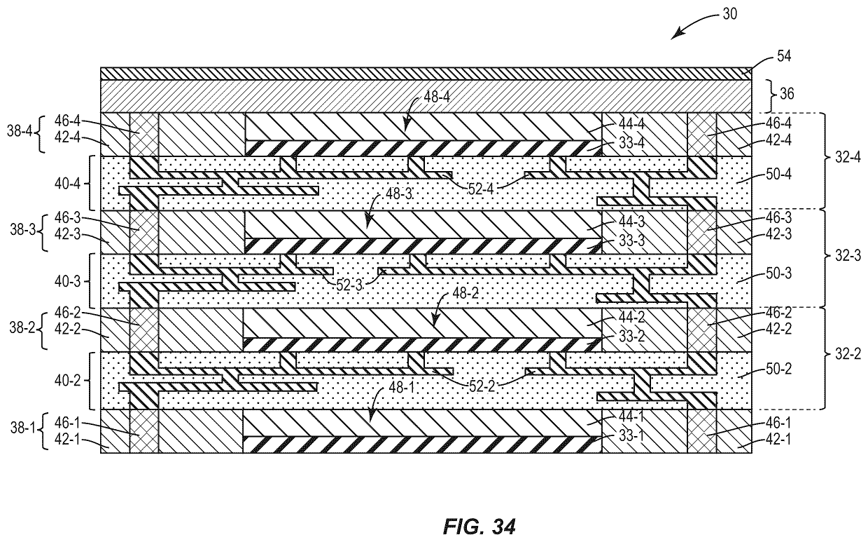

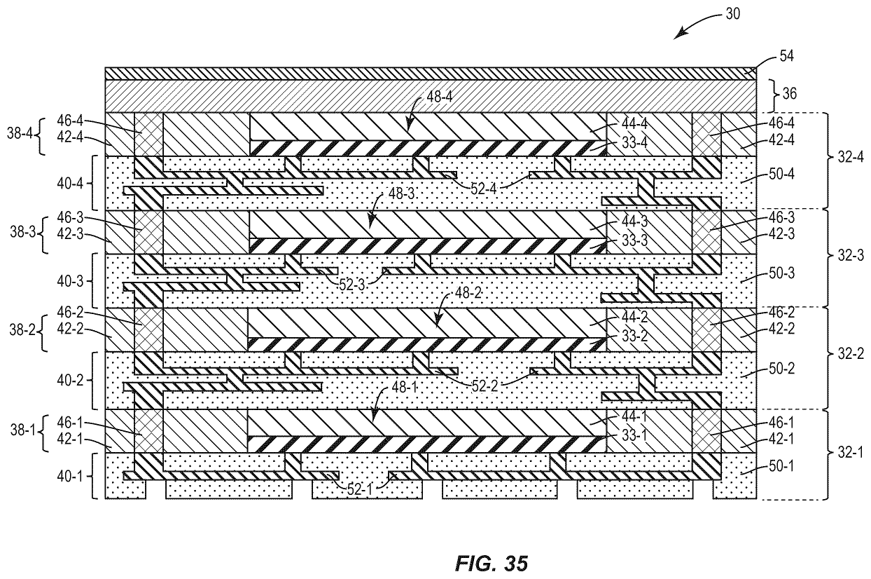

Next, the module carrier 80 is removed from the first die section 38-1, as illustrated in FIG. 34. Herein, the first thinned die 33-1 and the first vertical via structures 46-1 are exposed through the first mold compound 42-1 at the bottom of the first die section 38-1. The first redistribution structure 40-1 is then formed underneath the first die section 38-1, as illustrated in FIG. 35. The first redistribution structure 40-1 includes the first dielectric pattern 50-1 and the first redistribution interconnections 52-1 within the first dielectric pattern 50-1. Herein, the first redistribution interconnections 52-1 include some portions exposed through the first dielectric pattern 50-1 at the top of the first redistribution structure 40-1, such that the first redistribution interconnections 52-1 are configured to be connected to the first thinned die 33-1 and connected to the first vertical via structures 46-1 in the first die section 38-1. In addition, the first redistribution interconnections 52-1 also include some portions exposed through the first dielectric pattern 50-1 at the bottom of the first redistribution structure 40-1.

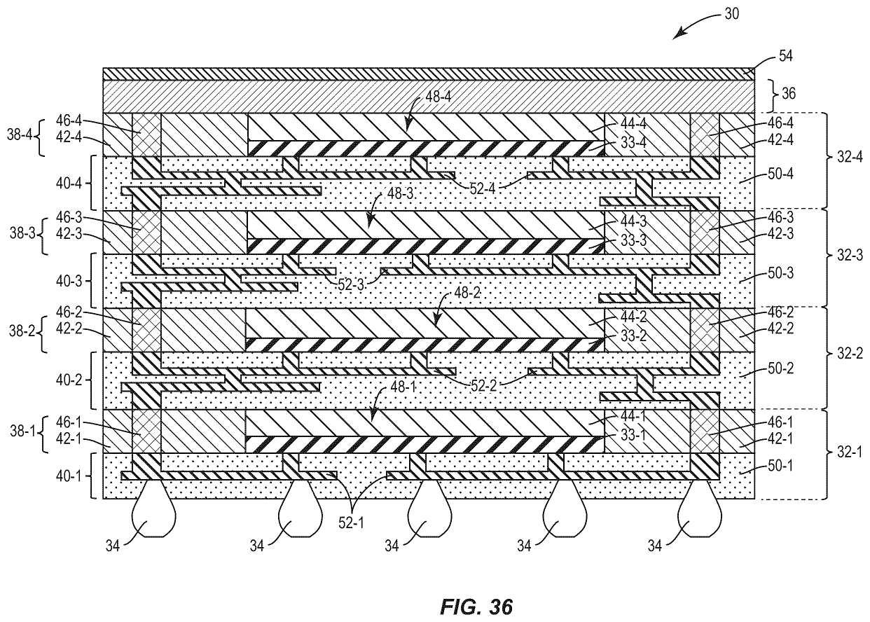

Lastly, the bump structures 34 are formed underneath the first redistribution structure 40-1 to provide the multi-level 3D package 30, as illustrated in FIG. 36. Each bump structure 34 is coupled to an exposed portion of the first redistribution interconnections 52-1 at the bottom of the first redistribution structure 40-1. Herein, the bump structures 34, which might be copper pillars or solder balls, are separate from each other and protrude from the first dielectric pattern 50-1.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A method of fabricating a multi-level three-dimensional (3D) package comprising:
forming a lower die section over a module carrier comprising:
deposing a lower thinned die and a lower mold compound over the module carrier, wherein the lower thinned die does not include a silicon substrate and has a thickness less than 100 micrometers, and the lower mold compound surrounds the lower thinned die and extends vertically beyond a top surface of the lower thinned die to define a lower opening over the lower thinned die and within the lower mold compound;
applying a lower intermediary mold compound, wherein the lower intermediary mold compound resides over the lower thinned die and fills the lower opening, and a top surface of the lower intermediary mold compound and a top surface of the lower mold compound are coplanar; and
forming lower vertical via structures extending through the lower mold compound to complete the lower die section;
forming an upper redistribution structure over the lower die section; and
forming an upper die section over the upper redistribution structure to provide an upper package level, comprising:
deposing an upper thinned die and an upper mold compound over the upper redistribution structure, wherein the upper thinned die does not include a silicon substrate and has a thickness less than 100 micrometers, and the upper mold compound surrounds the upper thinned die and extends vertically beyond a top surface of the upper thinned die to define an upper opening over the upper thinned die and within the upper mold compound; and
applying an upper intermediary mold compound, wherein the upper intermediary mold compound resides over the upper thinned die and fills the upper opening, and a top surface of the upper intermediary mold compound and a top surface of the upper mold compound are coplanar.

2. The method of claim 1 wherein deposing the lower thinned die and the lower mold compound comprises:
deposing a lower intact die and the lower mold compound over the module carrier, wherein:
the lower intact die includes a lower device region over the module carrier and a lower die substrate over the lower device region, such that a backside of the lower die substrate is a top surface of the lower intact die; and
the lower mold compound fully encapsulates the lower intact die;
thinning down the lower mold compound to expose the backside of the lower die substrate; and
removing the lower die substrate completely to provide the lower thinned die and define the lower opening over the lower thinned die and within the lower mold compound.

3. The method of claim 2 wherein applying the lower intermediary mold compound comprises:
applying the lower intermediary mold compound over the lower thinned die to provide a lower molding precursor; and
polishing the lower mold precursor, such that the top surface of the lower intermediary mold compound and the top surface of the lower mold compound are coplanar.

4. The method of claim 3 wherein forming the lower vertical via structures comprises:
after polishing the lower mold precursor, forming lower vertical via holes through the lower mold compound; and
forming the lower vertical via structures within the lower vertical via holes, respectively, to complete the lower die section.

5. The method of claim 3 wherein forming the lower vertical via structures comprises deposing the lower vertical via structures over the module carrier before deposing the lower mold compound, wherein:
after deposing the lower mold compound, each of the lower vertical via structures is fully encapsulated by the lower mold compound; and
a height of each of the lower vertical via structures is selected, such that after polishing the lower mold precursor, each of the lower vertical via structures can be exposed through the lower mold compound.

6. The method of claim 5 wherein each of the lower vertical via structures includes a seed layer directly over the module carrier and a metal or alloy material plated over the seed layer.

7. The method of claim 1 wherein deposing the upper thinned die and the upper mold compound comprises:
deposing an upper intact die and the upper mold compound over the upper redistribution structure, wherein:
the upper intact die includes an upper device region over the upper redistribution structure and an upper die substrate over the upper device region, such that a backside of the upper die substrate is a top surface of the upper intact die; and
the upper mold compound fully encapsulates the upper intact die;
thinning down the upper mold compound to expose the backside of the upper die substrate; and
removing the upper die substrate completely to provide the upper thinned die and define the upper opening over the upper thinned die and within the upper mold compound.

8. The method of claim 7 wherein applying the upper intermediary mold compound comprises:
applying the upper intermediary mold compound over the upper thinned die to provide an upper molding precursor; and
polishing the upper mold precursor, such that the top surface of the upper intermediary mold compound and the top surface of the upper mold compound are coplanar.

9. The method of claim 1 further comprising removing the module carrier, such that the lower thinned die and each of the lower vertical via structures are exposed through the lower mold compound at a bottom surface of the lower mold compound.

10. The method of claim 9 further comprising forming a lower redistribution structure underneath the lower die section.

11. The method of claim 10, wherein:
the lower redistribution structure includes a lower dielectric pattern and lower redistribution interconnections within the lower dielectric pattern;
the upper redistribution structure includes an upper dielectric pattern and upper redistribution interconnections within the upper dielectric pattern; and
the lower thinned die is connected to the upper thinned die through the lower redistribution interconnections in the lower redistribution structure, the lower vertical via structures in the lower die section, and the upper redistribution interconnections in the upper redistribution structure.

12. The method of claim 11 further comprising forming a plurality of bump structures underneath the lower redistribution structure, wherein:
each of the plurality of bump structures is connected to the lower redistribution interconnections through the lower dielectric pattern;
the plurality of bump structures are separate from each other and protrude from the lower dielectric pattern; and
the plurality of bump structures are copper pillars or solder balls.

13. The method of claim 1 further comprising forming a top protection structure over the upper die section, wherein:
the top protection structure is in contact with the upper mold compound and the upper intermediary mold compound in the upper die section; and
the top protection structure is configured to provide chemical and gas/air contamination protection.

14. The method of claim 13 further comprising applying a metal shield over the top protection structure, wherein the metal shield is configured to provide electromagnetic shielding of the multi-level 3D package.

15. The method of claim 1 wherein:
the upper intermediary mold compound is formed of one of a group consisting of an organic epoxy resin system, a molding material with a thermal conductivity higher than 50 W/mK, a molding material with a magnetic permeability higher than 50, and a molding material with an electric permittivity higher than 10; and
the lower intermediary mold compound is formed of one of a group consisting of an organic epoxy resin system, a molding material with a thermal conductivity higher than 50 W/mK, a molding material with a magnetic permeability higher than 50, and a molding material with an electric permittivity higher than 10.

16. The method of claim 1 wherein the upper thinned die and the lower thinned die are different types of dies.

17. The method of claim 16 wherein the upper intermediary mold compound and the lower intermediary mold compound are formed of different materials.

18. The method of claim 1 wherein:
at least one of the upper thinned die and the lower thinned die is an active die that includes an insulating layer, an active layer underneath the insulating layer, and a back-end-of-line (BEOL) portion underneath the active layer;
the active layer is configured to provide one or more active devices; and
the BEOL portion includes dielectric layers and metal structures within the dielectric layers, wherein the metal structures are configured to connect the active devices in the active layer to each other and/or configured to connect the active devices in the active layer to external components.

19. The method of claim 18 wherein:
the active die is formed from a silicon-on-insulator (SOI) structure;
the active layer of the active die is formed by integrating the one or more active devices in or on a silicon epitaxy layer of the SOI structure; and
the insulating layer of the active die is a buried oxide layer of the SOI structure.

20. The method of claim 1 wherein:
at least one of the upper thinned die and the lower thinned die is a passive die, which includes an insulating layer and a BEOL portion underneath the insulating layer; and
the BEOL portion includes dielectric layers and metal structures within the dielectric layers, wherein the metal structures are configured to provide one or more passive devices and configured to connect the passive devices to external components.
